(19) United States
(12) Patent Application Publication
(10) Pub. No.: US 2023/0291498 A1
(43) Pub. Date: Sep. 14, 2023

(54) METHOD AND APPARATUS FOR HYBRID AUTOMATIC REPEAT REQUEST IN COMMUNICATION SYSTEM USING POLAR CODES

(71) Applicant: ELECTRONICS AND TELECOMMUNICATIONS RESEARCH INSTITUTE, Daejeon (KR)

(72) Inventors: Jung Im KIM, Daejeon (KR); Jae Sheung SHIN, Daejeon (KR)

(73) Assignee: ELECTRONICS AND TELECOMMUNICATIONS RESEARCH INSTITUTE, Daejeon (KR)

(21) Appl. No.: 18/182,074

(22) Filed: Mar. 10, 2023

(30) Foreign Application Priority Data
Mar. 11, 2022 (KR) 10-2022-0030823

(51) Int. Cl. H04L 1/00; H04L 1/1812

(52) U.S. Cl. CPC H04L 1/0057; H04L 1/0071; H04L 1/1812

(57) ABSTRACT

An operation method of a transmitting node in a communication system may comprise:

generating 2N initial transmission bits by encoding N information bits to be transmitted to a receiving node of the communication system in a polar coding scheme; transmitting, to the receiving node, an initial transmission signal generated by modulating the 2N initial transmission bits; receiving, from the receiving node, a signal indicating that the initial transmission signal is not normally received; interleaving the N information bits through an interleaver to generate N interleaved bits; generating 2N first retransmission bits by encoding the N interleaved bits in the polar coding scheme; and transmitting, to the receiving node, a first retransmission signal generated by modulating the 2N first retransmission bits.

### CROSS-REFERENCE TO RELATED APPLICATIONS

This application claims priority to Korean Patent Application No. 10-2022-0030823, filed on Mar. 11, 2022, with the Korean Intellectual Property Office (KIPO), the entire contents of which are hereby incorporated by reference.

### BACKGROUND

### 1. Technical Field

Exemplary embodiments of the present disclosure relate to a technique for hybrid automatic repeat request (HARQ) in a communication system, and more specifically, to a technique for improving signal transmission and reception performance based on an HARQ scheme in a communication system using polar codes.

### 2. Related Art

With the development of information and communication technology, various wireless communication technologies are being developed. Representative wireless communication technologies include long term evolution (LTE) and new radio (NR) defined as the 3rd generation partnership project (3GPP) standards. The LTE may be one of 4th generation (4G) wireless communication technologies, and the NR may be one of 5th generation (5G) wireless communication technologies.

In a communication system, when a communication node transmits data to another communication node through a wireless channel, errors may occur in the data depending on a state of a wired/wireless channel. In particular, when communication signals are overcrowded and transmitted/received on limited communication resources, a probability of error occurrence may increase. Therefore, in order for a communication node receiving the transmitted data to accurately detect the data, error correction codes having excellent error correction capability may be required.

For example, a polar code, which is one of error correction codes, has been developed. The polar code may refer to a code for correcting errors based on a channel polarization phenomenon on a physical channel through which data is transmitted.

When the length of input data to be encoded is shorter than 1000 bits, the polar code may have superior encoding performance compared to a low density parity check (LDPC) code or turbo code generally used for channel coding on a data channel. Therefore, the polar code may be easily used for channel coding on a control channel where the length of data is limited to be short.

Meanwhile, in Narrowband-IoT (NB-IoT) technology, which is one of the Internet of Things (IoT) technologies, a number of terminals may operate to transmit and receive data of relatively short length and low urgency. Accordingly, when channel coding based on the polar code is applied to data transmission and reception operations of communication nodes in services with short data such as NB-IoT services, communication performance improvement can be expected.

In this reason, techniques for communication nodes that transmit and receive signals encoded according to a polar coding scheme to effectively perform a retransmission request and retransmission based on an HARQ scheme may be required.

Matters described as the prior arts are prepared to help understanding of the background of the present disclosure, and may include matters that are not already known to those of ordinary skill in the technology domain to which exemplary embodiments of the present disclosure belong.

### SUMMARY

Exemplary embodiments of the present disclosure provide a signal transmission and reception method and apparatus for communication nodes transmitting and receiving signals encoded according to a polar coding scheme to efficiently perform signal retransmission based on an HARQ scheme.

According to a first exemplary embodiment of the present disclosure, an operation method of a transmitting node in a communication system may comprise: generating 2N initial transmission bits by encoding N information bits to be transmitted to a receiving node of the communication system in a polar coding scheme, wherein N is a natural number equal to or greater than 1; transmitting, to the receiving node, an initial transmission signal generated by modulating the 2N initial transmission bits; receiving, from the receiving node, a signal indicating that the initial transmission signal is not normally received; interleaving the N information bits through an interleaver to generate N interleaved bits; generating 2N first retransmission bits by encoding the N interleaved bits in the polar coding scheme; and transmitting, to the receiving node, a first retransmission signal generated by modulating the 2N first retransmission bits.

The generating of the 2N initial transmission bits may comprise: inputting the N information bits and N frozen bits to a first polar encoder having 2N bit channels; and obtaining the 2N initial transmission bits output from the first polar encoder.

The generating of the 2N first retransmission bits may comprise: inputting the N interleaved bits and N frozen bits to a second polar encoder having 2N bit channels; and obtaining the 2N first retransmission bits output from the second polar encoder.

The operation method may further comprise: receiving, from the receiving node, a signal indicating that a k-th retransmission signal transmitted to the receiving node is not normally received, wherein k is a natural number equal to or greater than 1; generating 2N (k+1)-th retransmission bits; and transmitting, to the receiving node, a (k+1)-th retransmission signal generated by modulating the 2N (k+1)-th retransmission bits, wherein the 2N (k+1)-th retransmission bits correspond to a result of encoding the N interleaved bits in the polar coding scheme when k is an odd number, and correspond to a result of encoding the N information bits in the polar coding scheme when k is an even number.

The polar coding scheme may mean an encoding scheme by a polar encoder having 2N bit channels, and N bit channels to which N frozen bits are inputted among the 2N bit channels may be determined based on mutual information (MI) values of the respective 2N bit channels.

According to a second exemplary embodiment of the present disclosure, an operation method of a receiving node in a communication system may comprise: receiving a first transmission signal initially transmitted from a transmitting node of the communication system; performing a decoding operation on 2N first received bits obtained by demodulating the first transmission signal in a polar coding scheme, wherein N is a natural number equal to or greater than 1; transmitting, to the transmitting node, a signal indicating that the initially transmitted first transmission signal is not normally received, when an error is identified in the decoding operation on the 2N first received bits; generating 2N first interleaved bits by interleaving 2N first output bits output as a result of the decoding operation on the 2N first received bits; receiving a second transmission signal transmitted from the transmitting node based on the signal indicating that the initially transmitted first transmission signal is not normally received; demodulating the second transmission signal to obtain 2N second received bits; performing a decoding operation on the 2N second received bits based on the 2N first interleaved bits in the polar coding scheme; and restoring N information bits based on a result of the decoding operation on the 2N second received bits.

The performing of the decoding operation on the 2N first received bits may comprise: inputting the 2N first received bits to a first polar decoder having 2N bit channels; performing, by the first polar decoder, the decoding operation on the 2N first received bits; obtaining the 2N first output bits output from the first polar decoder, when no error is identified in the decoding operation on the 2N first received bits; and determining remaining N first output bits excluding N first output bits corresponding to frozen bits among the 2N first output bits as a result of restoring the N information bits.

The performing of the decoding operation on the 2N second received bits may comprise: inputting the 2N first interleaved bits to a second polar decoder having 2N bit channels; updating a second priori information term used in a decoding operation in the second polar decoder based on the 2N first interleaved bits; inputting the 2N second received bits to the second polar decoder; performing, by the second polar decoder, the decoding operation on the 2N second received bits based on the updated second priori information term and the 2N second received bits; obtaining 2N second output bits output from the second polar decoder as a result of the decoding operation on the 2N second received bits, when no error is identified in the decoding operation on the 2N second received bits; and determining N remaining second output bits excluding N second output bits corresponding to frozen bits among the 2N second output bits as a result of restoring the N information bits.

The performing of the decoding operation on the 2N second received bits may comprise: inputting the 2N first interleaved bits to a second polar decoder having 2N bit channels; updating a second prior information term used in a decoding operation in the second polar decoder based on the 2N first interleaved bits; inputting the 2N second received bits to the second polar decoder; performing, by the second polar decoder, the decoding operation on the 2N second received bits based on the updated second prior information term and the 2N second received bits; transmitting, to the transmitting node, a signal indicating that the second transmission signal is not normally received, when an error is identified in the decoding operation on the 2N second received bits; generating 2N first deinterleaved bits by deinterleaving 2N second output bits output from the second polar decoder as a result of the decoding operation on the 2N second received bits; and inputting the 2N first deinterleaved bits to a first polar decoder having 2N bit channels.

The operation method may further comprise: demodulating a (k+1)-th transmission signal transmitted from the transmitting node to obtain 2N (k+1)-th received bits, based on a signal indicating that a k-th transmission signal is not normally received, wherein k is a natural number equal to or greater than 1; updating a j-th priori information term used in a decoding operation in a j-th polar decoder, based on 2N k-th interleaved bits obtained by interleaving 2N k-th output bits output as a result of a decoding operation on 2N k-th received bits obtained by demodulating the k-th transmission signal; inputting the 2N-th (k+1)-th received bits to the j-th polar decoder; and performing, by the j -th polar decoder, a decoding operation on the 2N (k+1)-th received bits, based on the updated j-th priori information term and the 2N (k+1)-th received bits, wherein the j-th polar decoder corresponds to the second polar decoder when k is an odd number, and the j-th polar decoder corresponds to the first polar decoder when k is an even number.

According to a third exemplary embodiment of the present disclosure, a transmitting node transmitting signals to a receiving node in a communication system may comprise: a processor; a memory electronically communicating with the processor; and instructions stored in the memory, wherein when executed by the processor, the instructions cause the transmitting node to perform: generating 2N initial transmission bits by encoding N information bits to be transmitted to a receiving node of the communication system in a polar coding scheme, wherein N is a natural number equal to or greater than 1; transmitting, to the receiving node, an initial transmission signal generated by modulating the 2N initial transmission bits; receiving, from the receiving node, a signal indicating that the initial transmission signal is not normally received; interleaving the N information bits through an interleaver to generate N interleaved bits; generating 2N first retransmission bits by encoding the N interleaved bits in the polar coding scheme; and transmitting, to the receiving node, a first retransmission signal generated by modulating the 2N first retransmission bits.

In the generating of the 2N initial transmission bits, the instructions may further cause the transmitting node to perform: inputting the N information bits and N frozen bits to a first polar encoder having 2N bit channels; and obtaining the 2N initial transmission bits output from the first polar encoder.

In the generating of the 2N first retransmission bits, the instructions may further cause the transmitting node to perform: inputting the N interleaved bits and N frozen bits to a second polar encoder having 2N bit channels; and obtaining the 2N first retransmission bits output from the second polar encoder.

The instructions may further cause the transmitting node to perform: receiving, from the receiving node, a signal indicating that a k-th retransmission signal transmitted to the receiving node is not normally received, wherein k is a natural number equal to or greater than 1; generating 2N (k+1)-th retransmission bits; and transmitting, to the receiving node, a (k+1)-th retransmission signal generated by modulating the 2N (k+1)-th retransmission bits, wherein the 2N (k+1)-th retransmission bits correspond to a result of encoding the N interleaved bits in the polar coding scheme when k is an odd number, and correspond to a result of encoding the N information bits in the polar coding scheme when k is an even number.

According to exemplary embodiments of the HARQ method and apparatus in the communication system using polar codes, a transmitting node that transmits a signal based on the polar coding scheme may perform encoding on transmission bits by using different polar encoders or the same polar encoder during initial transmission and during HARQ retransmission. In HARQ retransmission, encoding is performed using an interleaver. The interleaver performs mapping by applying different relationships between input bits to the initial transmission and the retransmission, so that a probability (i.e., belief) of 1 and a probability of 0 can be propagated to each decoder (i.e., belief propagation) for the initial transmission and the retransmission.

### BRIEF DESCRIPTION OF DRAWINGS

FIG. 1 is a conceptual diagram illustrating an exemplary embodiment of a communication system.

FIG. 2 is a block diagram illustrating an exemplary embodiment of a communication node constituting a communication system.

FIG. 3 is a sequence chart illustrating an exemplary embodiment of a method for transmitting and receiving signals in a communication system.

FIGS. 4A and 4B are conceptual diagrams for describing an exemplary embodiment of a polar encoder and a polar decoder in a communication system.

FIGS. 5A and 5B are conceptual diagrams for describing a first polar encoder and a second polar encoder included in a transmitting node in an exemplary embodiment of a communication system.

FIGS. 6A to 6E are conceptual diagrams for describing an exemplary embodiment of a transmitting node and a receiving node in a communication system.

FIGS. 7A and 7B are conceptual diagrams for describing an exemplary embodiment of a method for transmitting and receiving a signal by a transmitting node and a receiving node in a communication system.

FIGS. 8A to 8D are conceptual diagrams for describing a second exemplary embodiment of a method for transmitting and receiving a signal by a transmitting node and a receiving node in a communication system.

### DETAILED DESCRIPTION OF THE EMBODIMENTS

Exemplary embodiments of the present disclosure are disclosed herein. However, specific structural and functional details disclosed herein are merely representative for purposes of describing exemplary embodiments of the present disclosure. Thus, exemplary embodiments of the present disclosure may be embodied in many alternate forms and should not be construed as limited to exemplary embodiments of the present disclosure set forth herein.

Accordingly, while the present disclosure is capable of various modifications and alternative forms, specific exemplary embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular exemplary embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A communication system to which exemplary embodiments according to the present disclosure are applied will be described. The communication system to which the exemplary embodiments according to the present disclosure are applied is not limited to the contents described below, and the exemplary embodiments according to the present disclosure may be applied to various communication systems. Here, the communication system may have the same meaning as a communication network.

Throughout the present disclosure, a network may include, for example, a wireless Internet such as wireless fidelity (WiFi), mobile Internet such as a wireless broadband Internet (WiBro) or a world interoperability for microwave access (WiMax), 2G mobile communication network such as a global system for mobile communication (GSM) or a code division multiple access (CDMA), 3G mobile communication network such as a wideband code division multiple access (WCDMA) or a CDMA2000, 3.5G mobile communication network such as a high speed downlink packet access (HSDPA) or a high speed uplink packet access (HSUPA), 4G mobile communication network such as a long term evolution (LTE) network or an LTE-Advanced network, 5G mobile communication network, B5G mobile communication network (6G mobile communication network), or the like.

Throughout the present disclosure, a terminal may refer to a mobile station, mobile terminal, subscriber station, portable subscriber station, user equipment, access terminal, or the like, and may include all or a part of functions of the terminal, mobile station, mobile terminal, subscriber station, mobile subscriber station, user equipment, access terminal, or the like.

Here, a desktop computer, laptop computer, tablet PC, wireless phone, mobile phone, smart phone, smart watch, smart glass, e-book reader, portable multimedia player (PMP), portable game console, navigation device, digital camera, digital multimedia broadcasting (DMB) player, digital audio recorder, digital audio player, digital picture recorder, digital picture player, digital video recorder, digital video player, or the like having communication capability may be used as the terminal.

Throughout the present disclosure, the base station may refer to an access point, radio access station, node B (NB), evolved node B (eNB), base transceiver station, mobile multihop relay (MMR)-BS, or the like, and may include all or part of functions of the base station, access point, radio access station, NB, eNB, base transceiver station, MMR-BS, or the like.

Hereinafter, preferred exemplary embodiments of the present disclosure will be described in more detail with reference to the accompanying drawings. In describing the present disclosure, in order to facilitate an overall understanding, the same reference numerals are used for the same elements in the drawings, and duplicate descriptions for the same elements are omitted.

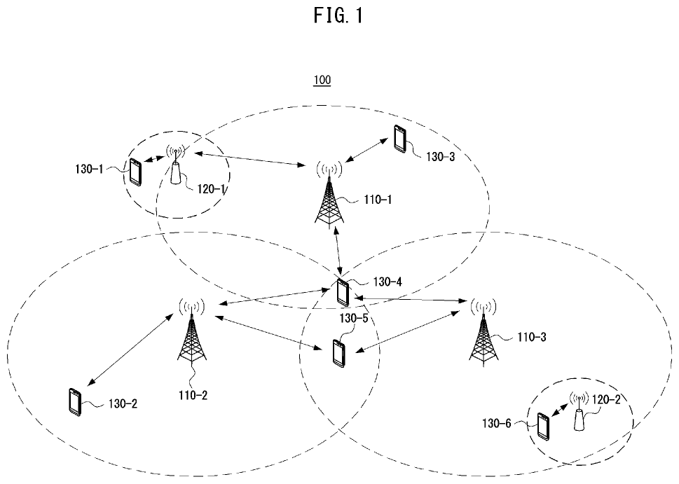

FIG. 1 is a conceptual diagram illustrating an exemplary embodiment of a communication system.

Referring to FIG. 1, a communication system 100 may comprise a plurality of communication nodes 110-1, 110-2, 110-3, 120-1, 120-2, 130-1, 130-2, 130-3, 130-4, 130-5, and 130-6. The plurality of communication nodes may support 4th generation (4G) communication (e.g., long term evolution (LTE), LTE-advanced (LTE-A)), 5th generation (5G) communication (e.g., new radio (NR)), or the like. The 4G communication may be performed in a frequency band of 6 gigahertz (GHz) or below, and the 5G communication may be performed in a frequency band of 6 GHz or above.

For example, for the 4G and 5G communications, the plurality of communication nodes may support a code division multiple access (CDMA) based communication protocol, a wideband CDMA (WCDMA) based communication protocol, a time division multiple access (TDMA) based communication protocol, a frequency division multiple access (FDMA) based communication protocol, an orthogonal frequency division multiplexing (OFDM) based communication protocol, a filtered OFDM based communication protocol, a cyclic prefix OFDM (CP-OFDM) based communication protocol, a discrete Fourier transform spread OFDM (DFT-s-OFDM) based communication protocol, an orthogonal frequency division multiple access (OFDMA) based communication protocol, a single carrier FDMA (SC-FDMA) based communication protocol, a non-orthogonal multiple access (NOMA) based communication protocol, a generalized frequency division multiplexing (GFDM) based communication protocol, a filter bank multi-carrier (FBMC) based communication protocol, a universal filtered multi-carrier (UFMC) based communication protocol, a space division multiple access (SDMA) based communication protocol, or the like.

In addition, the communication system 100 may further include a core network. When the communication system 100 supports the 4G communication, the core network may comprise a serving gateway (S-GW), a packet data network (PDN) gateway (P-GW), a mobility management entity (MME), and the like. When the communication system 100 supports the 5G communication, the core network may comprise a user plane function (UPF), a session management function (SMF), an access and mobility management function (AMF), and the like.

Meanwhile, each of the plurality of communication nodes 110-1, 110-2, 110-3, 120-1, 120-2, 130-1, 130-2, 130-3, 130-4, 130-5, and 130-6 constituting the communication system 100 may have the following structure.

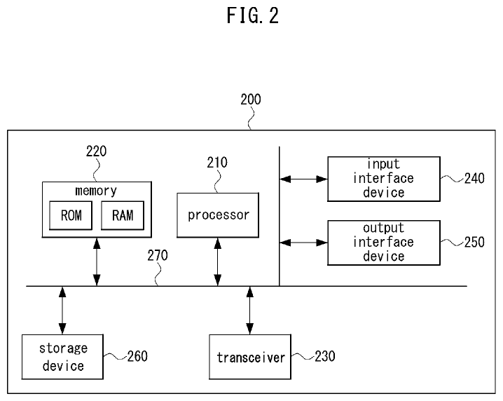

FIG. 2 is a block diagram illustrating an exemplary embodiment of a communication node constituting a communication system.

Referring to FIG. 2, a communication node 200 may comprise at least one processor 210, a memory 220, and a transceiver 230 connected to the network for performing communications. Also, the communication node 200 may further comprise an input interface device 240, an output interface device 250, a storage device 260, and the like. Each component included in the communication node 200 may communicate with each other as connected through a bus 270.

However, each component included in the communication node 200 may be connected to the processor 210 via an individual interface or a separate bus, rather than the common bus 270. For example, the processor 210 may be connected to at least one of the memory 220, the transceiver 230, the input interface device 240, the output interface device 250, and the storage device 260 via a dedicated interface.

The processor 210 may execute a program stored in at least one of the memory 220 and the storage device 260. The processor 210 may refer to a central processing unit (CPU), a graphics processing unit (GPU), or a dedicated processor on which methods in accordance with embodiments of the present disclosure are performed. Each of the memory 220 and the storage device 260 may be constituted by at least one of a volatile storage medium and a non-volatile storage medium. For example, the memory 220 may comprise at least one of read-only memory (ROM) and random access memory (RAM).

Referring again to FIG. 1, the communication system 100 may comprise a plurality of base stations 110-1, 110-2, 110-3, 120-1, and 120-2, and a plurality of terminals 130-1, 130-2, 130-3, 130-4, 130-5, and 130-6. The communication system 100 including the base stations 110-1, 110-2, 110-3, 120-1, and 120-2 and the terminals 130-1, 130-2, 130-3, 130-4, 130-5, and 130-6 may be referred to as an ‘access network’. Each of the first base station 110-1, the second base station 110-2, and the third base station 110-3 may form a macro cell, and each of the fourth base station 120-1 and the fifth base station 120-2 may form a small cell. The fourth base station 120-1, the third terminal 130-3, and the fourth terminal 130-4 may belong to cell coverage of the first base station 110-1. Also, the second terminal 130-2, the fourth terminal 130-4, and the fifth terminal 130-5 may belong to cell coverage of the second base station 110-2. Also, the fifth base station 120-2, the fourth terminal 130-4, the fifth terminal 130-5, and the sixth terminal 130-6 may belong to cell coverage of the third base station 110-3. Also, the first terminal 130-1 may belong to cell coverage of the fourth base station 120-1, and the sixth terminal 130-6 may belong to cell coverage of the fifth base station 120-2.

Here, each of the plurality of base stations 110-1, 110-2, 110-3, 120-1, and 120-2 may refer to a Node-B, a evolved Node-B (eNB), a base transceiver station (BTS), a radio base station, a radio transceiver, an access point, an access node, a road side unit (RSU), a radio remote head (RRH), a transmission point (TP), a transmission and reception point (TRP), an eNB, a gNB, or the like.

Here, each of the plurality of terminals 130-1, 130-2, 130-3, 130-4, 130-5, and 130-6 may refer to a user equipment (UE), a terminal, an access terminal, a mobile terminal, a station, a subscriber station, a mobile station, a portable subscriber station, a node, a device, an Internet of things (IoT) device, a mounted apparatus (e.g., a mounted module/device/terminal or an on-board device/terminal, etc.), or the like.

Meanwhile, each of the plurality of base stations 110-1, 110-2, 110-3, 120-1, and 120-2 may operate in the same frequency band or in different frequency bands. The plurality of base stations 110-1, 110-2, 110-3, 120-1, and 120-2 may be connected to each other via an ideal backhaul or a non-ideal backhaul, and exchange information with each other via the ideal or non-ideal backhaul. Also, each of the plurality of base stations 110-1, 110-2, 110-3, 120-1, and 120-2 may be connected to the core network through the ideal or non-ideal backhaul. Each of the plurality of base stations 110-1, 110-2, 110-3, 120-1, and 120-2 may transmit a signal received from the core network to the corresponding terminal 130-1, 130-2, 130-3, 130-4, 130-5, or 130-6, and transmit a signal received from the corresponding terminal 130-1, 130-2, 130-3, 130-4, 130-5, or 130-6 to the core network.

In addition, each of the plurality of base stations 110-1, 110-2, 110-3, 120-1, and 120-2 may support multi-input multi-output (MIMO) transmission (e.g., a single-user MIMO (SU-MIMO), multi-user MIMO (MU-MIMO), massive MIMO, or the like), coordinated multipoint (CoMP) transmission, carrier aggregation (CA) transmission, transmission in an unlicensed band, device-to-device (D 2 D) communications (or, proximity services (ProSe)), or the like. Here, each of the plurality of terminals 130-1, 130-2, 130-3, 130-4, 130-5, and 130-6 may perform operations corresponding to the operations of the plurality of base stations 110-1, 110-2, 110-3, 120-1, and 120-2, and operations supported by the plurality of base stations 110-1, 110-2, 110-3, 120-1, and 120-2. For example, the second base station 110-2 may transmit a signal to the fourth terminal 130-4 in the SU-MIMO manner, and the fourth terminal 130-4 may receive the signal from the second base station 110-2 in the SU-MIMO manner. Alternatively, the second base station 110-2 may transmit a signal to the fourth terminal 130-4 and fifth terminal 130-5 in the MU-MIMO manner, and the fourth terminal 130-4 and fifth terminal 130-5 may receive the signal from the second base station 110-2 in the MU-MIMO manner.

The first base station 110-1, the second base station 110-2, and the third base station 110-3 may transmit a signal to the fourth terminal 130-4 in the CoMP transmission manner, and the fourth terminal 130-4 may receive the signal from the first base station 110-1, the second base station 110-2, and the third base station 110-3 in the CoMP manner. Also, each of the plurality of base stations 110-1, 110-2, 110-3, 120-1, and 120-2 may exchange signals with the corresponding terminals 130-1, 130-2, 130-3, 130-4, 130-5, or 130-6 which belongs to its cell coverage in the CA manner. Each of the base stations 110-1, 110-2, and 110-3 may control D2D communications between the fourth terminal 130-4 and the fifth terminal 130-5, and thus the fourth terminal 130-4 and the fifth terminal 130-5 may perform the D2D communications under control of the second base station 110-2 and the third base station 110-3.

Hereinafter, repeated signal transmission methods in a wireless communication system will be described. Even when a method (e.g., transmission or reception of signals) performed at a first communication node among communication nodes is described, the corresponding second communication node may perform a method (e.g., reception or transmission of the signals) corresponding to the method performed at the first communication node. That is, when an operation of a receiving node is described, a corresponding transmitting node may perform an operation corresponding to the operation of the receiving node. Conversely, when an operation of a transmitting node is described, a corresponding receiving node may perform an operation corresponding to the operation of the transmitting node.

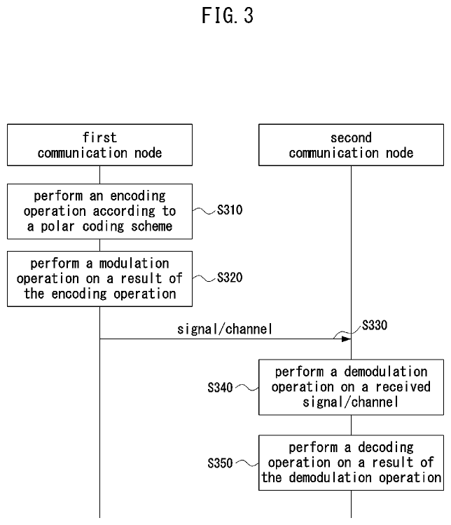

FIG. 3 is a sequence chart illustrating an exemplary embodiment of a method for transmitting and receiving signals in a communication system.

Referring to FIG. 3, a communication system may include a first communication node and a second communication node. The first communication node may transmit a signal/channel to the second communication node, and may be referred to as ‘transmitting node’. The second communication node may receive the signal/channel from the first communication node, and may be referred to as ‘receiving node’. When the first communication node is the base station shown in FIG. 1, the second communication node may be the terminal shown in FIG. 1. Alternatively, when the first communication node is the terminal shown in FIG. 1, the second communication node may be the base station or terminal shown in FIG. 1. Each of the first communication node and the second communication node may be configured identically or similarly to the communication node 200 shown in FIG. 2.

The first communication node may generate coded bits by performing an encoding operation according to a polar coding scheme on information bits corresponding to information to be transmitted (S310). Step S310 may be performed by a polar encoder included in the first communication node, and operations of the polar encoder may be controlled by a processor included in the first communication node (e.g., processor 210 shown in FIG. 2). In the encoding operation according to the polar coding scheme, the coded bits may be generated based on the information bits and frozen bits having a fixed value.

The first communication node may generate modulated symbols by performing a modulation operation on the coded bits or transmission symbols composed of the coded bits (S320). Step S 320 may be performed by a modulator included in the first communication node, and operations of the modulator may be controlled by the processor included in the first communication node (e.g., processor 210 shown in FIG. 2). The first communication node may transmit the modulated symbols (e.g., signal and/or channel generated based on the modulated symbols) through radio resources (S330). The second communication node may receive the signal and/or channel from the first communication node.

Here, a signal may be a reference signal (e.g., channel state information-reference signal (CSI-RS), demodulation-reference signal (DM-RS), phase tracking-reference signal (PT-RS), or the like. A channel may be a physical downlink control channel (PDCCH), a physical downlink shared channel (PDSCH), a physical uplink control channel (PUCCH), a physical uplink shared channel (PUSCH), a physical broadcast channel (PBCH), or a sidelink channel.

The second communication node may obtain demodulated symbols by performing a demodulation operation on the received signal and/or channel (S340). Step S340 may be performed by a demodulator included in the second communication node, and operations of the demodulator may be controlled by a processor included in the second communication node (e.g., processor 210 shown in FIG. 2). Here, the demodulated symbols may be soft bits (e.g., log likelihood ratio (LLR) values). The second communication node may obtain the information bits by performing a decoding operation on the soft bits (S350). Step S350 may be performed by a polar decoder included in the second communication node, and operations of the polar decoder may be controlled by the processor included in the second communication node (e.g., processor 210 shown in FIG. 2).

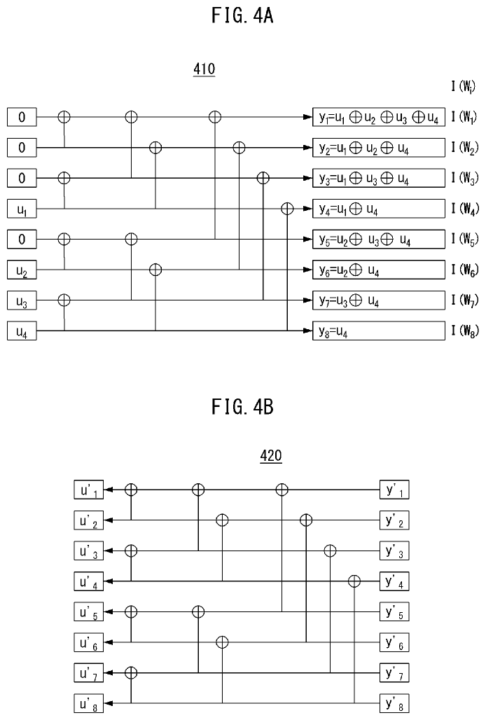

FIGS. 4A and 4B are conceptual diagrams for describing an exemplary embodiment of a polar encoder and a polar decoder in a communication system. Referring to FIGS. 4A and 4B, a belief (or bit capacity) of a communication channel may be polarized through polarization transform in a polar encoder performing encoding according to the polar coding scheme, and information or information bits to be transmitted may be transmitted through bit channels identified as having high belief (or bit capacity) as a result of the polarization transform. On the other hand, bit channels identified as having low belief (or bit capacity) may be filled with predefined bits (e.g., frozen bits). The polarization transform in the polar encoder may be defined as a Kronecker power of a square matrix, called as ‘kernel’. According to a signal encoded by the polar coding scheme based on polarization transform as described above, a process of sequentially decoding the information bits may be facilitated. Specifically, when bit channels for transmitting the information are appropriately selected and a sufficiently large channel capacity is guaranteed, all the information bits may be sequentially restored without error propagation. In the encoding operation according to the polar coding scheme, due to its structural characteristics, the number N of coded bits that can be generated may take a form of a power of a kernel size L (i.e., N=Lⁿ).

N input bits may be input to a polar encoder composed of N bit channels. The N input bits may include one or more information bits and one or more frozen bits. The input bits may include information bits uᵢ (i=1, 2, . . . ) and frozen bits having a value of 0. The polar encoder to which the N input bits are input may output N coded bits. Each coded bit may be expressed as yᵢ (i=0, 1, . . . , N−1). The coded bits yᵢ output from the polar encoder may constitute a transmission symbol.

When the transmission symbol composed of the coded bits yᵢ is modulated by a transmitting node and transmitted to a receiving node through a radio channel, the receiving node may obtain a demodulated symbol through a demodulation operation. Here, the demodulated symbol may consist of N demodulated bits. Each demodulated bit may be expressed as y′ᵢ (i=1, 2, . . . , N). In a polar decoder of the receiving node, output bits u′ᵢ (i=1, 2, . . . , N) may be obtained based on the respective demodulated bits y′ᵢ. Here, the output bits u′ᵢ may correspond to the input bits (i.e., the plurality of frozen bits and the plurality of information bits) input to the polar encoder at the transmitting node. The bits yᵢ coded in the polar encoder and the demodulated bits y′ᵢ input to the polar decoder may respectively correspond to input and output of the radio channel. The polar decoder of the receiving node may restore the information bits transmitted by the transmitting node based on a relationship between the coded bits yᵢ and the input bits at the polar encoder. Specifically, the polar decoder may obtain the output bits u′ᵢ from the demodulated bits y′ᵢ. Among the output bits u′ᵢ, output bits excluding output bits corresponding to the frozen bits may be regarded as a result of restoring the information bits.

Referring to FIG. 4A, the first exemplary embodiment of the polar encoder 410 may have a structure where N is 8. However, this is only an example for convenience of description, and exemplary embodiments of the present disclosure are not limited thereto. The polar encoder 410 having the structure where N is 8 may have 8 input nodes and 8 output nodes corresponding to 8 bit channels. A corresponding input bit may be input to each bit channel (or each input node). Each bit channel (or each output node) may output a coded bit yᵢ (i=1, 2, . . . , 8) calculated based on the structure of the polar encoder 410. The polar encoder 410 may obtain 8 coded bits yᵢ based on the 8 input bits.

Here, the 8 input bits may include 4 information bits uᵢ (i=1, 2, 3, 4) and 4 frozen bits. Among them, the information bits uᵢ may be mapped to bit channels having relatively high belief among the bit channels. On the other hand, the frozen bits may be mapped to bit channels having relatively low belief among the bit channels.

The belief of each of the bit channels constituting the polar encoder 410 may be calculated based on mutual information (MI). In FIG. 4A, I(Wᵢ) (i=1, 2, . . . , 8) may mean a result of calculating MI values between the respective input bits and all the bits of the polar encoder in a binary erasure channel (BEC) situation. Bit channels having a higher MI value I(Wᵢ) may be expected to have higher belief. For example, when values of I(W₄), I(W₆), I(W₇), and I(W₈) are relatively large, and values of I(W₁), I(W₂), I(W₃), and I(W₅) are relatively small among the 8 MI values I(Wᵢ), the polar encoder 410 may input the information bits uᵢ (i=1, 2, 3, 4) to the fourth, sixth, seventh and eighth channels (i.e., i=4, 6, 7, 8), and may input the frozen bits to the first, second, third and fifth channels (i.e., i=1, 2, 3, 5).

y₁ among the coded bits yᵢ calculated based on the structure of the polar encoder 410 may be calculated as y₁=u₁⊕u₂⊕u₃⊕u₄. y₂ among the coded bits yᵢ may be calculated as y₂=u₁⊕u₂⊕u₄. y₃ among the coded bits yᵢ may be calculated as y₃=u₁⊕u₃⊕u₄. y₄ among the coded bits yᵢ may be calculated as y₄=u₁⊕u₄. y₅ among the coded bits yᵢ may be calculated as y₅=u₂⊕u₃⊕u₄. y₆ among the coded bits yᵢ may be calculated as y₆=u₂⊕u₄. y₇ among the coded bits yᵢ may be calculated as y₇=u₃⊕u₄. y₈ among the coded bits yᵢ may be calculated as y₈=u₄. In the above-described calculation result of the coded bits, ⊕ may mean an exclusive OR (XOR) operation.

Referring to FIG. 4B, the first exemplary embodiment of the polar decoder 420 may have a structure where N is 8. However, this is only an example for convenience of description, and exemplary embodiments of the present disclosure are not limited thereto. The polar decoder 420 having the structure where N is 8 may have 8 input nodes and 8 output nodes corresponding to 8 bit channels. A corresponding demodulated bit y′ᵢ (i=1, 2, . . . , 8) may be input to each bit channel (or each input node). An operation in the polar decoder 420 of the receiving node may correspond to a reverse process of the operation in the polar encoder 410 of the transmitting node. The polar decoder 420 of the receiving node may restore the information bits transmitted by the transmitting node based on the relationship between the input bits and the coded bits yᵢ at the polar encoder 410 of the transmitting node.

Specifically, each bit channel (or each output node) may output an output bit u′ᵢ (i=1, 2, . . . , 8) calculated based on the structure of the polar decoder 420. The polar decoder 420 may obtain output bits u′ᵢ based on the 8 demodulated bits y′ᵢ. Among the 8 output bits u′ᵢ, 4 output bits may correspond to the frozen bits, and the remaining 4 output bits may correspond to the information bits. For example, u′₄, u′₆, u′₇, and u′₈ among the 8 output bits u′ᵢ may correspond to the information bits uᵢ (i=1, 2, 3, 4), and u′₁, u′₂, u′₃, and u′₅ among the 8 output bits u′ᵢ may correspond to the frozen bits. That is, u′₄, u′₆, u′₇, and u′₈ excluding u′₁, u′₂, u′₃, and u′₅ corresponding to the frozen bits among the output bits u′ᵢ obtained based on the demodulated bits y′ᵢ input to the polar decoder 420 may correspond to a result of restoring the information bits uᵢ.

The polar decoder 420 may perform decoding on the demodulated bits y′ᵢ based on an iterative decoding scheme. The polar decoder 420 may perform decoding on the demodulated bits y′ᵢ based on a maximum a posterior (MAP) decoding scheme among iterative decoding schemes. In the MAP decoding scheme, when restoring an arbitrary information bit uₖ based on an arbitrary demodulated bit y′, the polar decoder 420 may determine a decision value of uₖ as +1 (i.e., u′ₖ=+1) if a value of p(y′|uₖ=+1) is greater than p(y′|uₖ=−1) (i.e., p(y′|uₖ=+1)>p(y′|uₖ=−1)). On the other hand, the polar decoder 420 may determine a decision value of uₖ as −1 (i.e., u′ₖ=−1) if the value of p(y′|uₖ=+1) is smaller than p(y′|uₖ=−1) (i.e., p(y′|uₖ=+1)<p(y′|uₖ=−1)). In this regard, in the polar decoder 420, the value of L(uₖ) may be defined as Equation 1.

$$L ( {u}_{k} ) = log ( \frac{p ( {u}_{k} = + 1 \vert {y}^{′} )}{p ( {u}_{k} = - 1 \vert {y}^{′} )} ) = log ( \frac{p ( {y}^{′} \vert {u}_{k} = + 1 )}{p ( {y}^{′} \vert {u}_{k} = - 1 )} ) + log ( \frac{p ( {u}_{k} = + 1 )}{p ( {u}_{k} = - 1 )} ) \qquad [ Equation 1 ]$$

Here, a term log

$$( \frac{p ( {u}_{k} = + 1 )}{p ( {u}_{k} = - 1 )} )$$

may be referred to as ‘a priori information’ or ‘priori information term’. In the iterative decoding scheme, the priori information term (i.e., log

$$( \frac{p ( {u}_{k} = + 1 )}{p ( {u}_{k} = - 1 )} ) )$$

may be updated for each iteration, and accordingly, accuracy of the value of L(uₖ) may be improved, and performance of the decoding operation may be improved. Here, in the first round of iterations according to the iterative decoding scheme (e.g., first decoding based on an initially transmitted signal), the priori information term may be set to 0.

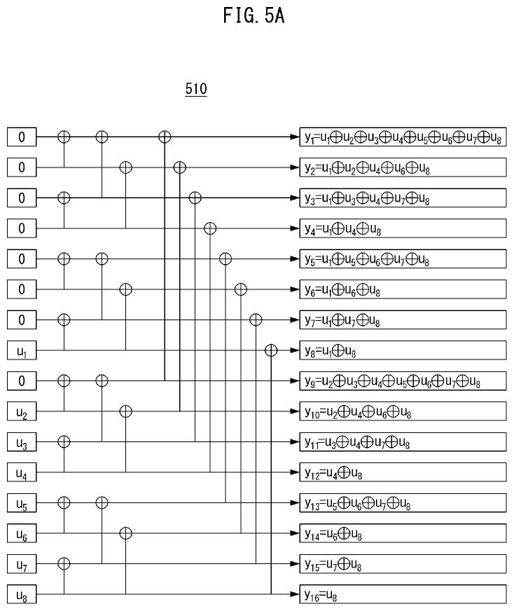

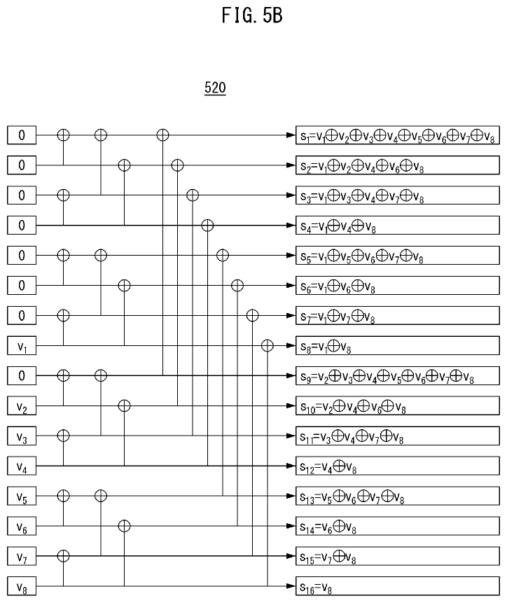

FIGS. 5A and 5B are conceptual diagrams for describing a first polar encoder and a second polar encoder included in a transmitting node in an exemplary embodiment of a communication system.

Referring to FIGS. 5A and 5B, a transmitting node including a polar encoder may obtain coded bits by encoding information bits to be transmitted to a receiving node through the polar encoder, and transmit the coded bits by modulating them into a radio signal. The receiving node may obtain demodulated bits by demodulating the radio signal received from the transmitting node, and may restore the information bits by decoding the demodulated bits through a polar decoder. In an exemplary embodiment of the communication system, the transmitting node may include a plurality of polar encoders. For example, the transmitting node may include a first polar encoder and a second polar encoder. Hereinafter, in describing the first polar encoder and the second polar decoder included in the transmitting node with reference to FIGS. 5A and 5B, descriptions overlapping those described with reference to FIGS. 3 to 4B may be omitted.

Referring to FIG. 5A, a first polar encoder 510 may have a structure where N is 16. However, this is only an example for convenience of description, and exemplary embodiments of the present disclosure are not limited thereto. The first polar encoder 510 having the structure where N is 16 may have 16 input nodes and 16 output nodes corresponding to 16 bit channels. A corresponding input bit may be input to each bit channel (or each input node). Each bit channel (or each output node) may output coded bit yᵢ (i=1, 2, . . . , 16) calculated based on the structure of the first polar encoder 510. The first polar encoder 510 may obtain 16 coded bits yᵢ based on the 16 input bits.

Here, the 16 input bits may include 8 information bits uᵢ (i=1, 2, . . . , 8) and 8 frozen bits. Among them, the information bits uᵢ may be mapped to bit channels having relatively high belief among the bit channels. On the other hand, the frozen bits may be mapped to bit channels having relatively low belief among the bit channels. For example, the first polar encoder 510 may input the information bits uᵢ (i=1, 2, . . . , 8) to the eighth and the tenth to sixteenth channels (i.e., i=8, 10, 11, . . . , 16), and input the frozen bits to the first to seventh and ninth channels (i.e., i=1, 2, . . . , 7, 9).

y₁ among the coded bits yᵢ calculated based on the structure of the first polar encoder 510 may be calculated as y₁=u₁⊕u₂⊕u₃⊕u₄⊕u₅⊕u₆⊕u₇⊕u₈. y₂ among the coded bits yᵢ may be calculated as y₂=u₁⊕u₂⊕u₄⊕u₆⊕u₈. y₃ among the coded bits yᵢ may be calculated as y₃=u₁⊕u₃⊕u₄⊕u₇⊕u₈. y₄ among the coded bits yᵢ may be calculated as y₄=u₁⊕u₄⊕u₈. y₅ among the coded bits yᵢ may be calculated as y₅=u₁⊕u₅⊕u₆⊕u₇⊕u₈. y₆ among the coded bits yᵢ may be calculated as y₆=u₁⊕u₆⊕u₈. y₇ among the coded bits yᵢ may be calculated as y₇=u₁⊕u₇⊕u₈. y₈ among the coded bits yᵢ may be calculated as y₈=u₁⊕u₈. y₉ among the coded bits yᵢ may be calculated as y₉=u₂⊕u₃⊕u₄⊕u₅⊕u₆⊕u₇⊕u₈. y₁₀ among the coded bits yᵢ may be calculated as y₁₀=u₂⊕u₄⊕u₆⊕u₈. y₁₁ among the coded bits yᵢ may be calculated as y₁₁=u₃⊕u₄⊕u₇⊕u₈. y₁₂ among the coded bits yᵢ may be calculated as y₁₂=u₄⊕u₈. y₁₃ among the coded bits yᵢ may be calculated as y₁₃=u₅⊕u₆⊕u₇⊕u₈. y₁₄ among the coded bits yᵢ may be calculated as y₁₄=u₆⊕u₈. y₁₅ among the coded bits yᵢ may be calculated as y₁₅=u₇⊕u₈. y₁₆ among the coded bits yᵢ may be calculated as y₁₆=u₈.

Referring to FIG. 5B, a second polar encoder 520 may have a structure where N is 16. However, this is only an example for convenience of description, and exemplary embodiments of the present disclosure are not limited thereto. The second polar encoder 520 having the structure where N is 16 may have 16 input nodes and 16 output nodes corresponding to 16 bit channels.

Interleaved bits interleaved by a separate interleaver may be input to the second polar encoder 520. Specifically, the transmitting node may interleave the information bits uᵢ (i=1, 2, . . . , 8) to be transmitted to the receiving node through the separate interleaver to generate the interleaved bits vᵢ (i=1, 2, . . . , 8). The transmitting node may input the interleaved bits vi to the second polar encoder 520.

A corresponding input bit may be input to each bit channel (or each input node) of the second polar encoder 520. Each bit channel (or each output node) may output a coded bit sᵢ (i=1, 2, . . . , 16) calculated based on the structure of the second polar encoder 520. The second polar encoder 520 may obtain 16 coded bits sᵢ based on the 16 input bits. The second polar encoder 520 may input the interleaved bits vᵢ (i=1, 2, . . . , 8) to the eighth and tenth to sixteenth channels (i.e., i=8, 10, 11, . . . , 16), and input the frozen bits to the first to seventh and ninth channels (i.e., i=1, 2, . . . , 7, 9).

s₁ among the coded bits sᵢ calculated based on the structure of the second polar encoder 520 may be calculated as s₁=v₁⊕v₂⊕v₃⊕v₄⊕v₅⊕v₆⊕v₇⊕v₈. s₂ among the coded bits sᵢ may be calculated as s₂=v₁⊕v₂⊕v₄⊕v₆⊕v₈. s₃ among the coded bits sᵢ may be calculated as s₃=v₁⊕v₃⊕v₄⊕v₇⊕v₈. s₄ among the coded bits sᵢ may be calculated as s₄=v₁⊕v₄⊕v₈. s₅ among the coded bits sᵢ may be calculated as s₅=v₁⊕v₅⊕v₆⊕v₇⊕v₈. s₆ among the coded bits sᵢ may be calculated as s₆=v₁⊕v₆⊕v₈. s₇ among the coded bits sᵢ may be calculated as s₇=v₁⊕v₇⊕v₈. s₈ among the coded bits sᵢ may be calculated as s₈=v₁⊕v₈. s₉ among the coded bits sᵢ may be calculated as s₉=v₂⊕v₃⊕v₄⊕v₅⊕v₆⊕v₇⊕v₈. s₁₀ among the coded bits sᵢ may be calculated as s₁₀=v₂⊕v₄⊕v₆⊕v₈. s₁₁ among the coded bits sᵢ may be calculated as s₁₁=v₃⊕v₄⊕v₇⊕v₈. s₁₂ among the coded bits sᵢ may be calculated as s₁₂=v₄⊕v₈. s₁₃ among the coded bits sᵢ may be calculated as s₁₃=v₅⊕v₆⊕v₇⊕v₈. s₁₄ among the coded bits sᵢ may be calculated as s₁₄=v₆⊕v₈. s₁₅ among the coded bits sᵢ may be calculated as s₁₅=v₇⊕v₈. s₁₆ among the coded bits sᵢ may be calculated as s₁₆=v₈.

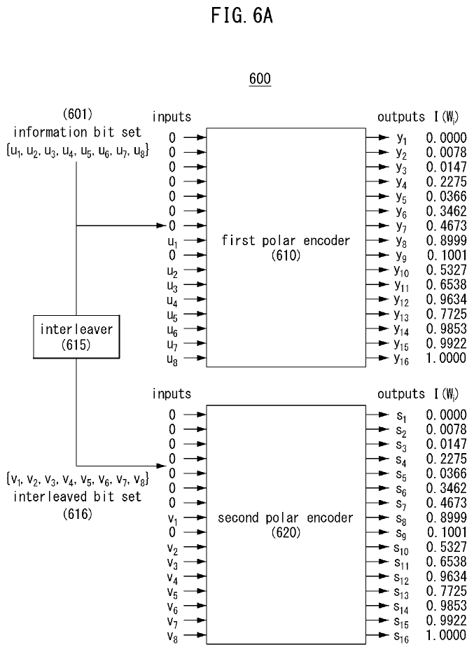

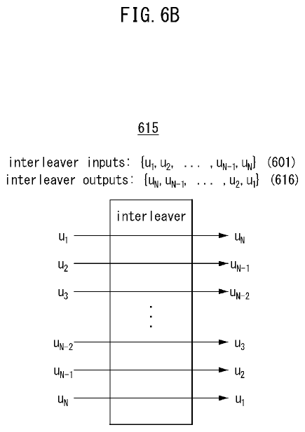

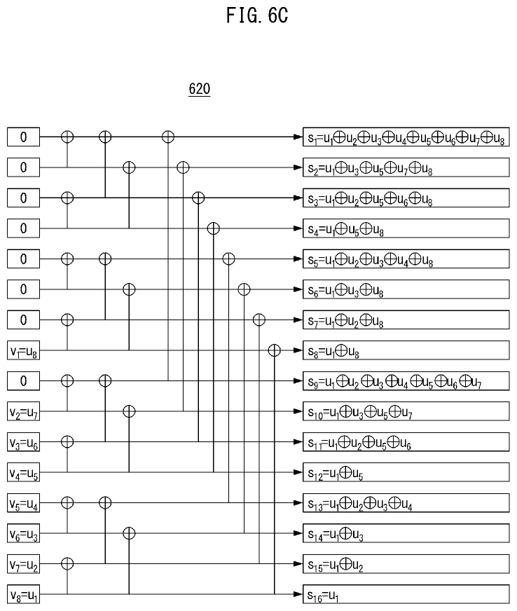

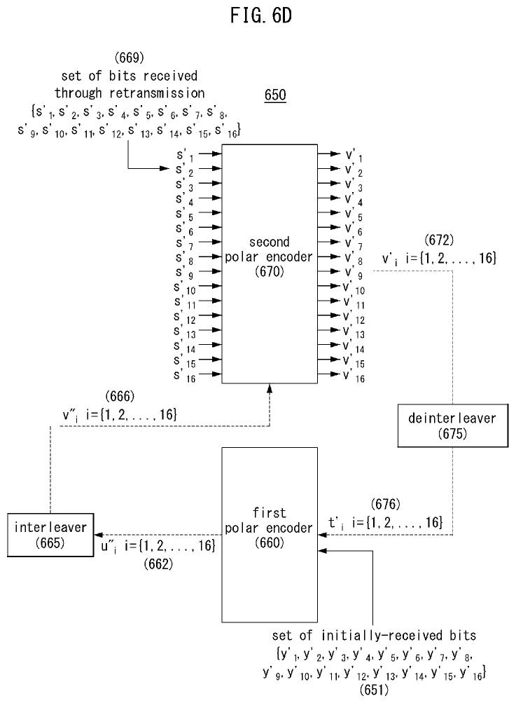

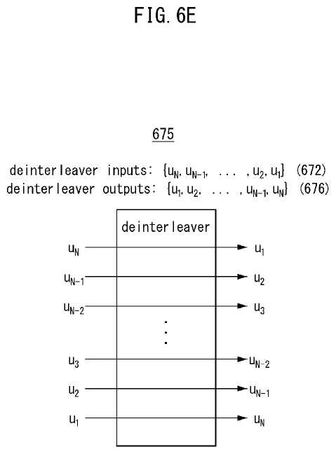

FIGS. 6A to 6E are conceptual diagrams for describing an exemplary embodiment of a transmitting node and a receiving node in a communication system.

Referring to FIGS. 6A to 6E, in a communication system, a transmitting node 600 and a receiving node 650 may transmit and receive signals based on a polar coding scheme. The transmitting node 600 may include a plurality of polar encoders to encode information bits to be transmitted to the receiving node 650. The transmitting node 600 may use different polar encoders to encode the information bits during initial transmission and during retransmission. For example, the transmitting node 600 may generate coded bits by encoding the information bits using the first polar encoder 610 during initial transmission. The transmitting node 600 may retransmit the information bits when a NACK signal according to an HARQ scheme is received as a feedback for the initially transmitted signal.

Throughout the present disclosure, a NACK signal may correspond to a feedback signal for a specific signal previously transmitted. The NACK signal may be a signal indicating that the specific signal is not normally received. For example, in an exemplary embodiment of the communication system, a first communication node may transmit a first signal to a second communication node, and the second communication node may transmit a NACK signal to the first communication node as feedback for the first signal. In this case, the NACK signal may indicate that the first signal was not normally received by the second communication node. The first communication node may recognize that the first signal was not normally received by the second communication node based on the NACK signal received from the second communication node.

The transmitting node 600 may generate coded bits by encoding the information bits using the second polar encoder 620 during retransmission. The transmitting node 600 may modulate the coded bits generated using the first polar encoder 610 and/or the second polar encoder 620, and transmit modulated bits to the receiving node 650. Here, the first polar encoder 610 and the second polar encoder 620 may be the same as or similar to the first polar encoder 510 and the second polar encoder 520 described with reference to FIGS. 5A and 5B, respectively.

The receiving node 650 may receive a signal transmitted from the transmitting node 600. The receiving node 650 may demodulate the received signal to obtain demodulated bits. The receiving node 650 may include a plurality of polar decoders to decode the demodulated bits to restore the information bits. The receiving node 650 may decode the demodulated bits using different polar decoders during initial transmission and during retransmission. For example, when receiving the initially transmitted signal from the transmitting node 600, the receiving node 650 may restore the information bits by decoding the demodulated bits using a first polar decoder 660. When the receiving node 650 receives the retransmitted signal from the transmitting node 600, the information bits may be restored by decoding the demodulated bits using a second polar decoder 670. The transmitting node 600 may modulate the coded bits generated using the first polar encoder 610 and/or the second polar encoder 620, and transmit the modulated bits to the receiving node 650. Here, the first polar decoder 660 and the second polar decoder 670 may have a structure for performing operations corresponding to a reverse process of the operations in the first polar encoder 610 and the second polar encoder 620, respectively. The first polar decoder 660 and the second polar decoder 670 may be the same as or similar to the polar decoder 420 described with reference to FIG. 4B, respectively.

Referring to FIG. 6A, the transmitting node 600 may include the first polar encoder 610 and the second polar encoder 620. The transmitting node 600 may encode an information bit set {u₁, u₂, . . . u₈} 601 corresponding to information or data to be transmitted to the receiving node 650 using the polar coding scheme.

When initially transmitting the information bit set 601, the transmitting node 600 may encode the information bit set 601 through the first polar encoder 610. Specifically, the transmitting node 600 may input the information bit set 601 to the first polar encoder 610 when initially transmitting the information bit set 601. Here, the first polar encoder 610 may be the same as or similar to the first polar encoder 510 described with reference to FIG. 5A. The first polar encoder 610 may perform an operation on the input information bit set 601 and 8 frozen bits to output 16 coded bits yᵢ (i=1, 2, . . . , 16). Among the 16 bit channels (i=1, 2, . . . 16) constituting the first polar encoder 610, bit channels to which the frozen bits are input and bit channels to which the information bit set 601 is input may be determined based on belief for the respective bit channels. The belief for each bit channel may be determined based on an MI value I(Wᵢ) for each bit channel. For example, in an exemplary embodiment of the communication system, among the 16 channels constituting the first polar encoder 610, the eighth and tenth to sixteenth channels (i.e., i=8, 10, 11, . . . , 16) may have a relatively high MI value I(Wᵢ), and the first to seventh and ninth channels (i.e., i=1, 2, . . . , 7, 9) may have a relatively low MI value I (Wᵢ). In this case, the first polar encoder 610 may sequentially input the information bits uᵢ (i=1, 2, . . . , 8) included in the information bit set 601 to the eighth and tenth to sixteenth channels among 16 channels, and may sequentially input the frozen bits to the first to seventh and ninth channels.

The 16 coded bits yᵢ encoded and output by the first polar encoder 610 for initial transmission may be referred to as ‘initial transmission bits yᵢ’. The transmitting node 600 may generate an initial transmission signal by modulating the initial transmission bits yᵢ output from the first polar encoder 610. The transmitting node 600 may transmit the generated initial transmission signal to the receiving node 650. Meanwhile, the transmitting node 600 may further perform an additional encoding operation before modulating the initial transmission bits yᵢ.

On the other hand, when retransmitting the information bit set 601, the transmitting node 600 may encode the information bit set 601 through the second polar encoder 620. Specifically, the transmitting node 600 may input the information bit set 601 to an interleaver 615 when retransmitting the information bit set 601. Here, the interleaver 615 may have the same or similar structure as that shown in FIG. 6B.

Referring to FIG. 6B, the interleaver 615 may interleave a plurality of input bits and output a plurality of interleaved bits. For example, N input bits uᵢ (i=1, 2, . . . , N) included in the input bit set 601 may be input to the interleaver 615. In an exemplary embodiment of the communication system, N may be 8. The input bit set 601 may be the same as or similar to the information bit set 601 described with reference to FIG. 6B.

The interleaver 615 may interleave the N input bits uᵢ (i=1, 2, . . . , N) to output N interleaved bits uᵢ (i=N, N−1, . . . , 1). In other words, the interleaver 615 may output N interleaved bits vᵢ (i=1, 2, . . . , N) based on the N input bits uᵢ (i=1, 2, . . . , N). Here, vᵢ and uᵢ may have a relationship as shown in Equation 2.

vᵢ=u_{N+1-i} (i=1, 2, . . . , N) [Equation 2]

Referring to Equation 2, v₁=u_{N}, v₂=u_{N-1}, v₃=u_{N-2}, v_{N-2}=u₃, v_{N-1}=u₂, and v_{N}=u₁. The interleaved bits vᵢ (i=1, 2, . . . , N) may be regarded as corresponding to a reverse order of the input bits uᵢ (i=1, 2, . . . , N).

When the input bit set 601 including N input bits uᵢ is input, the interleaver 615 may output an interleaved bit set 616 including the N interleaved bits vᵢ.

Referring again to FIG. 6A, the transmitting node 600 may input the information bit set {u₁, u₂, . . . u₈} 601 to be retransmitted to the receiving node 650 into the interleaver 615 to generate or obtain the interleaved bit set {v₁, v₂, . . . v₈} 616. The bits of the interleaved bit set 616 may be regarded as being obtained by arranging the bits of the information bit set 601 in the reverse order. The transmitting node 600 may input the interleaved bit set 616 to the second polar encoder 620. Here, the second polar encoder 620 may be the same as or similar to the second polar encoder 510 described with reference to FIG. 5A. The second polar encoder 620 may perform an operation on the input interleaved bit set 616 and 8 frozen bits to output 16 coded bits sᵢ (i=1, 2, . . . , 16). Among the 16 bit channels (i=1, 2, . . . , 16) constituting the second polar encoder 620, bit channels to which the frozen bits are input and bit channels to which the interleaved bit set 616 is input may be determined based on belief for the respective bit channels. The belief for each bit channel may be determined based on an MI value I(Wᵢ) for each bit channel. For example, in an exemplary embodiment of the communication system, the eighth and tenth to sixteenth channels (i.e., i=8, 10, 11, . . . , 16) among 16 channels constituting the second polar encoder 620 may have a relatively high MI value I(Wᵢ), and the first to seventh and ninth channels (i.e., i=1, 2, . . . , 7, 9) may have a relatively low MI value I (Wᵢ). In this case, the second polar encoder 620 may sequentially input the interleaved bits vᵢ (i=1, 2, . . . 8) included in the interleaved bit set 616 to the eighth and tenth to sixteenth channels, and may sequentially input the frozen bits to the first to seventh and ninth channels.

16 coded bits sᵢ encoded and output from the second polar encoder 620 for retransmission may be referred to as ‘retransmission bits sᵢ’. The transmitting node 600 may generate a retransmission signal by modulating the retransmission bits sᵢ output from the second polar encoder 620. The transmitting node 600 may transmit the generated retransmission signal to the receiving node 650. Meanwhile, the transmitting node 600 may further perform an additional encoding operation before modulating the retransmission bits sᵢ.

Referring to FIG. 6C, the interleaved bits vᵢ (i=1, 2, . . . 8) included in the interleaved bit set 616 describe d with reference to FIG. 6A may be input to the second polar encoder 620 of the transmitting node 600. Here, the interleaved bits vᵢ input to the second polar encoder 620 and the information bits uᵢ described with reference to FIG. 6A may have a relationship as shown in Equation 3.

vᵢ=u₉₋ᵢ (i=1, 2, . . . , 8) [Equation 3]

The second polar encoder 620 may perform operations on the interleaved bits vᵢ. The second polar encoder 620 may sequentially input the interleaved bits vᵢ (i=1, 2, . . . 8) to the eighth and tenth to sixteenth channels among the 16 channels, and may sequentially input the frozen bits to the first to seventh and ninth channels. The second polar encoder 620 may output coded bits sᵢ (i=1, 2, . . . , 16) through the encoding operation. Here, referring to the technical characteristics of the second polar encoder 520 described with reference to FIG. 5B and the relationship between interleaved bits vᵢ and information bits uᵢ shown in Equation 3, s₁ among the coded bits sᵢ calculated in the second polar encoder 620 may be calculated as s₁=u₈⊕u₇⊕u₆⊕u₅⊕u₄⊕u₃⊕u₂⊕u₁. s₂ among the coded bits sᵢ may be calculated as s₂=u₈⊕u₇⊕u₅⊕u₃⊕u₁. s₃ among the coded bits sᵢ may be calculated as s₃=u₈⊕u₆⊕u₅⊕u₂⊕u₁. s₄ among the coded bits sᵢ may be calculated as s₄=u₈⊕u₅⊕u₁. s₅ among the coded bits sᵢ may be calculated as s₅=u₈⊕u₄⊕u₃⊕u₂⊕u₁. s₆ among the coded bits sᵢ may be calculated as s₆=u₈⊕u₃⊕u₁. s₇ among the coded bits sᵢ may be calculated as s₇=u₈⊕u₂⊕u₁. s₈ among the coded bits sᵢ may be calculated as s₈=u₈⊕u₁. s₉ among the coded bits sᵢ may be calculated as s₉=u₇⊕u₆⊕u₅⊕u₄⊕u₃⊕u₂⊕u₁. s₁₀ among the coded bits sᵢ may be calculated as s₁₀=u₇⊕u5⊕u₃⊕u₁. s₁₁ among the coded bits sᵢ may be calculated as s₁₁=u₆⊕u₅⊕u₂⊕u₁. s₁₂ among the coded bits sᵢ may be calculated as s₁₂=u₅⊕u₁. s₁₃ among the coded bits sᵢ may be calculated as s₁₃=u₄⊕u₃⊕u₂⊕u₁. s₁₄ among the coded bits sᵢ may be calculated as s₁₄=u₃⊕u₁. s₁₅ among the coded bits sᵢ may be calculated as s₁₅=u₂⊕u₁. s₁₆ among the coded bits sᵢ may be calculated as s₁₆=u₁.

Referring to FIGS. 5A and 6C, the coded bits sᵢ (i=1, 2, . . . , 16) output from the second polar encoder 620 may have a different coding gain than the coded bits yᵢ (i=1, 2, . . . , 16) output from the first polar encoder 510. Specifically, s₁ and s₈ among sᵢ may be regarded as corresponding to y₁ and y₈ and results of XOR operations of the same information bits, respectively. That is, s₁=y₁=u₁⊕u₂⊕u₃⊕u₄⊕u₅⊕u₆⊕u₇⊕u₈, and s₈=y₈=u₁⊕u₈. On the other hand, the remaining sᵢ (i=2, 3, 4, 5, 6, 7, 9, 10, 11, 12, 13, 14, 15, 16) excluding s₁ and s₈ may be regarded as corresponding to yᵢ (i=2, 3, 4, 5, 6, 7, 9, 10, 11, 12, 13, 14, 15, 16) and results of XOR operations of different information bits, respectively. This means that the coded bits sᵢ (i=1, 2, . . . , 16) output from the second polar encoder 620 may be regarded as being more polarized (i.e., polarization phenomenon is more intensified) as compared to the coded bits yᵢ (i=1, 2, . . . , 16) output from the first polar encoder 510. In other words, the coded bits (i=1, 2, . . . , 16) output from the second polar encoder 620 may be regarded as having a larger coding gain according to the polarization phenomenon as compared to the coded bits yᵢ (i=1, 2, . . . , 16) output from the first polar encoder 510.

In an exemplary embodiment of the communication system, assuming that the transmitting node encodes a plurality of bits x₁, x₂, x₃, and x₄ using a channel encoder (i.e., polar encoder) to which the polar coding scheme is applied and initially transmits them, a relationship between the plurality of bits x₁, x₂, x₃, and x₄ in a transmission signal may be configured as x₁⊕x₂=0 and x₃⊕x₄=0. In this case, the receiving node receiving the initially transmitted transmission signal may obtain information on a probability that x₁ and/or x₂ is 1 or 0, respectively, based on the relationship between x₁ and x₂, and may obtain information on a probability that x₃ and/or x₄ is 1 or 0, respectively, based on the relationship between x₃ and x₄.

Meanwhile, as described with reference to FIGS. 5A and 6C, when the transmitting node performs retransmission, more polarized bits may be transmitted through interleaving by the interleaver. For example, the relationship between the plurality of bits x₁, x₂, x₃, and x₄ in a retransmission signal may be configured as x₁⊕x₃=0 and x₂⊕x₄=0. In this case, the receiving node receiving the retransmission signal may obtain information on a probability that x₁ and/or x₃ is 1 or 0, respectively, based on the relationship between x₁ and x₃, and may obtain information on a probability that x₂ and/or x₄ is 1 or 0, respectively, based on the relationship between x₂ and x₄. That is, when the transmitting node performs retransmission, more polarized bits may be transmitted through interleaving by the interleaver, so that the receiving node can perform restoration of bits by using both probability information obtained during initial transmission and probability information obtained during retransmission. Accordingly, the performance of the restoration operation at the receiving node may be improved.

FIGS. 6A to 6C shows the exemplary embodiment of the transmitting node 600 based on the exemplary embodiment in which the transmitting node 600 performs encoding operations based on the first polar encoder 610 and the second polar encoder 620 that are different from each other. However, this is only an example for convenience of description, and exemplary embodiments of the present disclosure are not limited thereto. For example, in another exemplary embodiment of the transmitting node 600, the transmitting node 600 may perform encoding of an information bit set during initial transmission and encoding of an interleaved bit set during retransmission through a single polar encoder.

In the retransmission signal transmitted based on the transmitting node 600 and the second polar encoder 620 which are described with reference to FIGS. 6A to 6C, a coding gain due to channel polarization may be further maximized. The receiving node 650 may restore information bits uᵢ based on the initial transmission signal and the retransmission signal transmitted from the transmitting node 600. Here, since the initial transmission signal and the retransmission signal have different coding gains, decoding performance at the receiving node 650 may be improved. The decoding and restoration operations of the receiving node 650 will be described in more detail with reference to FIG. 6D below.

Referring to FIG. 6D, the receiving node 650 may receive the initial transmission signal or the retransmission signal transmitted from the transmitting node 600. The receiving node 650 may demodulate the initial transmission signal transmitted from the transmitting node 600 to obtain first received bits y′ᵢ (i=1, 2, . . . , 16). In other words, the receiving node 650 may demodulate the initial transmission signal transmitted from the transmitting node 600 to obtain a first received bit set {y′₁, y′₂, . . . , y′₁₆} 651. The first received bit set 651 may also be referred to as ‘initially-received bit set 651’.

The receiving node 650 may perform decoding by inputting the first received bits y′ᵢ included in the first received bit set 651 to the first polar decoder 660. The first polar decoder 660 may output first output bits u″ᵢ (i=1, 2, . . . , 16) as a result of a decoding operation on the first received bits y′ᵢ.

The first polar decoder 660 may perform decoding based on the iterative decoding scheme or the MAP decoding scheme described with reference to FIG. 4B. Here, in the decoding operation on the first received bits y′ᵢ included in the first received bit set 651, the priori information term described with reference to FIG. 4B may be set to 0.

The first polar decoder 660 may output the first output bits u″ᵢ as a result of restoring the initial transmission signal when no error is identified in the decoding operation on the first received bits y′ᵢ. Among the first output bits u″ᵢ, the first output bits u″ᵢ (i=8, 10, 11, . . . , 16) excluding bits corresponding to the frozen bits (e.g., u″ᵢ (i=1, 2, . . . , 7, 9)) may correspond to a result of restoring the transmission bits uᵢ (i=1, 2, . . . , 8) that the transmitting node 600 intended to transmit. In other words, the first output bit set {u″₁, u″₂, . . . , u″₁₆} 662 including the first output bits u″ᵢ output from the first polar decoder 660 may be regarded as including a result of restoring the bits of the information bit set 601 and the 8 frozen bits described with reference to FIG. 6A. The receiving node 650 may determine that u″₈, u″₁₀, u″₁₁, u″₁₂, u″₁₃, u″₁₄, u″₁₅, and u″₁₆ excluding bits corresponding to the frozen bits among the first output bits u″ᵢ correspond to a result of restoring the information bits u₁, u₂, u₃, u₄, u₅, u₆, u₇, and u₈ that the transmitting node intended to transmit, respectively.

Meanwhile, when an error is identified in the decoding operation on the first received bits y′ᵢ, the receiving node 650 may transmit a NACK signal according to the HARQ scheme to the transmitting node 600. When an error is identified in the decoding operation on the first received bits y′ᵢ, the first polar decoder 660 may transmit the first output bit set 662 to the interleaver 665. The interleaver 665 may have the same or similar structure as the interleaver 615 described with reference to FIG. 6B. The interleaver 665 may have a structure where N is changed to 16 from the interleaver 615 described with reference to FIG. 6B.

The interleaver 665 may interleave bits u″ᵢ included in the first output bit set 662 output from the first polar decoder 660 to output first priori information bits v″ᵢ (i=1, 2, . . . , 16). Here, the first prior information bits v″ᵢ and the first output bits u″ᵢ may have a relationship as shown in Equation 4.

v″ᵢ=u″₁₇₋ᵢ (i=1, 2, . . . , 16) [Equation 4]

The interleaver 665 may input a first priori information bit set {v″₁, v″₂, . . . , v″₁₆} 666 including the first priori information bits v″ᵢ to the second polar decoder 670. The second polar decoder 670 may calculate the priori information term described with reference to FIG. 4B based on the first priori information bit set 666. In other words, the second polar decoder 670 may update the priori information term based on the first priori information bit set 666 generated by interleaving the first output bit set 662 output from the first polar decoder 660 in the interleaver 665.

Meanwhile, the receiving node 650 may receive the retransmission signal transmitted from the transmitting node 600 based on the NACK signal. The receiving node 650 may demodulate the retransmission signal transmitted from the transmitting node 600 to obtain second received bits s′ᵢ (i=1, 2, . . . , 16). In other words, the receiving node 650 may demodulate the retransmission signal transmitted from the transmitting node 600 to obtain a second received bit set {s′₁, s′₂, . . . , s′₁₆} 669. The second received bit set 669 may also be referred to as ‘a set of bits received through retransmission’ 669.

The receiving node 650 may perform decoding by inputting the second received bits s′ᵢ included in the second received bit set 669 to the second polar decoder 670. The second polar decoder 670 may output second output bits v′ᵢ (i=1, 2, . . . , 16) as a result of the decoding operation on the second received bits s′ᵢ. The second polar decoder 670 may perform the decoding operation on bits included in the second received bit set 669 based on the priori information term updated based on the first priori information bit set 666 and the second received bit set 669.

The second polar decoder 670 may output the second output bits as a result of restoring the retransmission signal when an error is not identified in the decoding operation on the second received bits s′ᵢ. Among the second output bits the second output bits (e.g., v′ᵢ (i=8, 10, 11, . . . , 16)) excluding bits (e.g., v′ᵢ (i=1, 2, . . . , 7, 9)) corresponding to the frozen bits may correspond to a result of restoring the interleaved bits vᵢ (i=1, 2, . . . , 8) that the transmitting node 600 intended to transmit. In other words, a second output bit set {v′₁, v′₂, . . . , v′₁₆} 672 including the second output bits v′ᵢ output from the second polar decoder 670 may be regarded as including a result of restoring the bits of the interleaved bit set 616 and the 8 frozen bits described with reference to FIGS. 6A to 6C. In this case, the receiving node 650 may transmit an ACK signal according to the HARQ scheme to the transmitting node 600. The receiving node 650 may determine that v′₈, v′₁₀, v′₁₁, v′₁₂, v′₁₃, v′₁₄, v′₁₅, and v′₁₆ excluding the bits corresponding to the frozen bits among the second output bits v′ᵢ correspond to a result of restoring the interleaved bits v₁, v₂, v₃, v₄, v₅, v₆, v₇, and v₈ that the transmitting node 600 intended to transmit, respectively. In other words, the receiving node 650 may determine that v′₁₆, v′₁₅, v′₁₄, v′₁₃, v′₁₂, v′₁₁, v′₁₀, and v′₈ according to a reverse order of the bits excluding the bits corresponding to the frozen bits among the second output bits v′ᵢ correspond to a result of restoring u₁, u₂, u₃, u₄, u₅, u₆, u₇, and u₈ that the transmitting node 600 intended to transmit, respectively.

Meanwhile, when an error is identified in the decoding operation on the second received bits s′ᵢ, the receiving node 650 may transmit a NACK signal according to the HARQ scheme to the transmitting node 600. When an error is identified in the decoding operation on the second received bits s′ᵢ, the second polar decoder 670 may transmit a second output bit set 672 to a deinterleaver 675. The deinterleaver 675 may perform a deinterleaving operation corresponding to a reverse operation of the interleaving operation of the interleaver 615 described with reference to FIG. 6B. Technical characteristics of the deinterleaver 675 will be described in more detail with reference to FIG. 6E below.

Referring to FIG. 6E, the deinterleaver 675 may deinterleave a plurality of input bits to output a plurality of deinterleaved bits. For example, N input bits uᵢ (i=N, N−1, . . . , 1) may be input to the deinterleaver 675. In an exemplary embodiment of the communication system, N may be 8 or 16.

The deinterleaver 675 may deinterleave the N input bits uᵢ (i=N, N−1, . . . , 1) to output N deinterleaved bits uᵢ (i=1, 2, . . . , N).

Referring again to FIG. 6D, the deinterleaver 675 may deinterleave bits v′ᵢ included in the second output bit set 672 output from the first polar decoder 670 to output second priori information bits t′ᵢ (i=1, 2, . . . , 16). Here, the second priori information bits t′ᵢ and the second output bits v′ᵢ may have a relationship as shown in Equation 4.

t′ᵢ=v′₁₇₋ᵢ (i=1, 2, . . . , 16) [Equation 5]

The deinterleaver 675 may input a first priori information bit set {t′₁, t′₂, . . . , t′₁₆} 676 including the second priori information bits t′ᵢ to the first polar decoder 660. The first polar decoder 660 may calculate the priori information term described with reference to FIG. 4B based on the second priori information bit set 676. In other words, the first polar decoder 670 may update the priori information term based on the second priori information set 676 generated by the deinterleaver 675 deinterleaving the second output bit set 676 output from the second polar decoder 670. The receiving node 650 may perform the decoding operation on the first received bits y′ᵢ (i=1, 2, . . . , 16) again based on the priori information term updated based on the second prior information bit set 676.

FIG. 6D illustrates an exemplary embodiment of the receiving node 650 based on the exemplary embodiment in which the receiving node 650 performs encoding operations based on the first polar decoder 660 and the second polar decoder 670 that are different from each other. However, this is only an example for convenience of description, and exemplary embodiments of the present disclosure are not limited thereto. For example, in another exemplary embodiment of the receiving node 650, the receiving node 650 may perform decoding on the first received bit set and decoding on the second received bit set through one polar decoder.

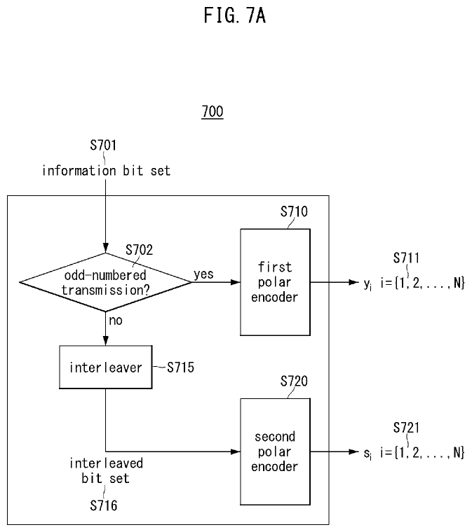

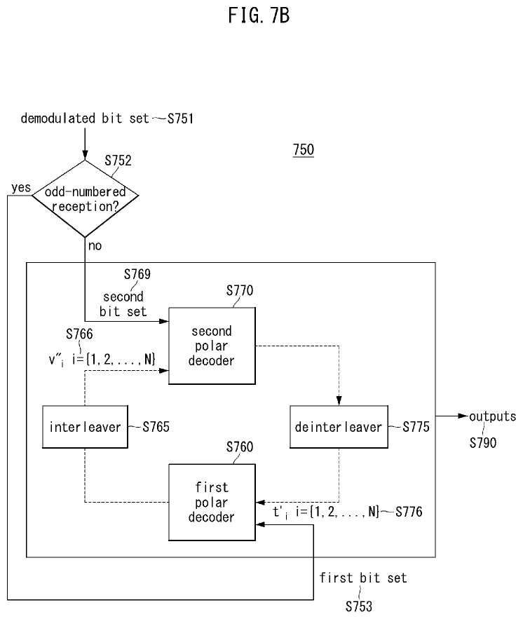

Meanwhile, the receiving node 650 may receive a second retransmission signal from the transmitting node 600 based on the NACK signal. The first polar decoder 610 of the receiving node 650 may perform a decoding operation on demodulated bits obtained by demodulating the second retransmission signal retransmitted by the transmitting node 600. Technical characteristics of such the decoding operation will be described in more detail with reference to FIGS. 7A and 7B below.

FIGS. 7A and 7B are conceptual diagrams for describing an exemplary embodiment of a method for transmitting and receiving a signal by a transmitting node and a receiving node in a communication system.

Referring to FIGS. 7A and 7B, in a communication system, a transmitting node 700 and a receiving node 750 may transmit and receive signals based on a polar coding scheme. The transmitting node 700 may include a plurality of polar encoders (e.g., a first polar encoder and a second polar encoder) to encode information bits to be transmitted to the receiving node 750. Here, the first polar encoder included in the transmitting node 700 may be the same as or similar to the first polar encoder 610 described with reference to FIG. 6A. The second polar encoder included in the transmitting node 700 may be the same as or similar to the second polar encoder 620 described with reference to FIGS. 6A and 6C. The receiving node 750 may receive a signal transmitted from the transmitting node 700. The receiving node 750 may include a first polar decoder and a second polar decoder to restore the information bits by decoding demodulated bits obtained by demodulating the received signal. The first polar decoder included in the receiving node 750 may be the same as or similar to the first polar decoder 660 described with reference to FIG. 6D. The second polar decoder included in the receiving node 750 may be the same as or similar to the second polar decoder 670 described with reference to FIG. 6D. Hereinafter, in describing an exemplary embodiment of the method for transmitting and receiving a signal by the transmitting node and the receiving node in the communication system with reference to FIGS. 7A and 7B, descriptions overlapping those described with reference to FIGS. 3 to 6E may be omitted.

Referring to FIG. 7A, the transmitting node 700 may include the first polar encoder and the second polar encoder. The transmitting node 700 may encode an information bit set {u₁, u₂, . . . u₈} 601 corresponding to information or data to be transmitted to the receiving node 750 using the polar coding scheme.

The transmitting node 700 may identify an information bit set {u₁, u₂, . . . u_{N}} to be transmitted to the receiving node 750 (S701). The transmitting node 700 may identify which transmission round the information bit set to be initially transmitted or retransmitted to the receiving node 750 belongs to. The transmitting node 700 may identify whether the number k of transmissions (k is a natural number) including initial transmission for the information bit set to be transmitted to the receiving node 750 is an odd number or an even number (S702). In other words, when the transmitting node 700 retransmits the information bit set to the receiving node 750, it may be identified whether it is an even-numbered retransmission or an odd-numbered retransmission (S702).

When k is an odd number (S702), the transmitting node 700 may encode N information bits included in the information bit set through the first polar encoder (S710). In other words, when the transmitting node 700 performs initial transmission or even-numbered retransmission of the information bit set to the receiving node 750 (S702), the N information bits included in the information bit set may be encoded through the first polar encoder (S710). The encoding operation according to step S710 may be the same as or similar to the encoding operation of the first polar encoder 610 described with reference to FIG. 6A. The first polar encoder may output 2N coded bits yᵢ (i=1, 2, . . . , 2N) as a result of encoding the information bits (S711). The transmitting node 700 may generate a k-th transmission signal by modulating the 2N coded bits yᵢ output from the first polar encoder. The transmitting node 700 may transmit the k-th transmission signal to the receiving node 750.

On the other hand, when k is an even number (S702), the transmitting node 700 may encode the N information bits included in the information bit set through the second polar encoder (S720). In other words, when the transmitting node 700 performs an odd-numbered retransmission of the information bit set to the receiving node 750 (S702), the N information bits included in the information bit set may be encoded through the second polar encoder (S720). Specifically, when k is an even number (S702), the transmitting node 700 may input the N information bits included in the information bit set to the interleaver. Here, the interleaver may be the same as or similar to that described with reference to FIGS. 6A and/or 6B. The interleaver may generate or obtain an interleaved bit set {v₁, v₂, . . v₈} through the interleaving operation (S715) on the input information bit set {u₁, u₂, . . . u_{N}} (S716). The transmitting node 700 may input the interleaved bit set to the second polar encoder. Here, the second polar encoder may be the same as or similar to the second polar encoder 620 described with reference to FIGS. 6A and 7C. The second polar encoder may perform encoding on the interleaved bits (S720). The encoding operation according to step S720 may be the same as or similar to the encoding operation of the first polar encoder 610 described with reference to FIG. 6A. The second polar encoder may output 2N coded bits sᵢ (i=1, 2, . . . , 2N) as a result of encoding the interleaved bits (S721). The transmitting node 700 may generate the k-th transmission signal by modulating the 2N coded bits sᵢ output from the second polar encoder. The transmitting node 700 may transmit the k-th transmission signal to the receiving node 750.

In FIG. 7A, an exemplary embodiment of the method for transmitting and receiving a signal has been described based on the exemplary embodiment in which the transmitting node 700 performs encoding operations using the first polar encoder and the second polar encoder that are different from each other. However, this is only an example for convenience of description, and exemplary embodiments of the present disclosure are not limited thereto. For example, in another exemplary embodiment of the signal transmission/reception method, the transmitting node 700 may perform the encoding operation according to step S710 or the encoding operation according to step S720 through one polar encoder.

Referring to FIG. 7B, the receiving node 750 may receive the k-th transmission signal transmitted from the transmitting node 700. The receiving node 750 may demodulate the k-th transmission signal transmitted from the transmitting node 700 to obtain a demodulated bit set. The demodulated bit set obtained in step S751 may be referred to as ‘k-th bit set’. The receiving node 750 may identify whether the transmission of the k-th transmission signal is an odd-numbered transmission or even-numbered transmission (S752).

When k is an odd number (S752), the receiving node 750 may input the k-th bit set obtained in step S751 to the first polar decoder (S753). In other words, when the k-th transmission signal is an initial transmission signal or an even-numbered retransmission signal, the receiving node 750 may input the k-th bit set obtained in step S751 to the first polar decoder (S753). The k-th bit set input to the first polar decoder may be expressed as {y′₁, y′₂, . . . . , y′2_{N}}. The first polar decoder may perform a decoding operation on the k-th bit set (S760). The first polar decoder may output first output bits u″ᵢ (i=1, 2, . . . , 2N) as a result of the decoding operation on bits y′ᵢ included in the k-th bit set. The decoding operation according to step S760 may be performed based on the iterative decoding scheme or the MAP decoding scheme described with reference to FIG. 4B. Here, when k is 1 (that is, when the k-th transmission signal is an initial transmission signal), the priori information term described with reference to FIG. 4B may be set to 0 in the decoding operation in step S760. On the other hand, when k is not 1 (i.e., when the k-th transmission signal is an even-numbered retransmission signal), the first polar decoder may update the priori information terminal based on a second priori information set t′ᵢ (i=1, 2, . . . , 2N) input as a result of decoding the k-th transmission signal, and perform the decoding operation according to step S760 based on the updated priori information term.

When an error is not identified in the decoding operation according to step S760, the receiving node 750 may transmit an ACK signal according to the HARQ scheme to the transmitting node 700. When an error is not identified in the decoding operation in step S760, the receiving node 750 may determine that N bits excluding bits corresponding to the frozen bits among the first output bits u″ᵢ (i=1, 2, . . . , 2N) correspond to a result of restoring the information bits uᵢ (i=1, 2, . . . , N) that the transmitting node 700 intended to transmit. The receiving node 750 may output the bits corresponding to the result of restoring the information bits uᵢ (i=1, 2, . . . , N) (S790).

On the other hand, when an error is identified in the decoding operation according to step S760, the receiving node 750 may transmit a NACK signal according to the HARQ scheme to the transmitting node 700. When an error is identified in the decoding operation in step S760, the receiving node 750 may input the first output bits u″ᵢ (i=1, 2, . . . , 2N) to the interleaver. The interleaver included in the receiving node 750 may be the same as or similar to the interleaver 615 described with reference to FIG. 6B or the interleaver 665 described with reference to 6D. The interleaver may have a structure in which N is changed to 2N from the interleaver 615 described with reference to FIG. 6B. The receiving node 750 may perform interleaving on the first output bits u″ᵢ (i=1, 2, . . . , 2N) through the interleaver (S765). The interleaver may output first priori information bits v″ᵢ (i=1, 2, . . . , 2N) as a result of the interleaving operation (S766). Here, the first priori information bits v″ᵢ and the first output bits u″ᵢ may have a relationship as shown in Equation 6.

v″ᵢ=u″_{2N+N-i} (i=1, 2, . . . , 2N) [Equation 6]

The receiving node 750 may input a first priori information bit set {v″₁, v″₂, . . . , v″_{2N}} including the first priori information bits v″ᵢ to the second polar decoder. The second polar decoder may calculate the priori information term described with reference to FIG. 4B based on the first priori information bit set. In other words, the second polar decoder may update the priori information term based on the first priori information bit set generated by interleaving the first output bit set output from the first polar decoder in the interleaver. The second polar decoder may perform decoding on a (k+1)-th bit set based on the updated priori information term and the (k−1)-th bit set obtained by demodulating a (k+1)-th reception signal.

On the other hand, when k is an even number (S752), the receiving node 750 may input the k-th bit set obtained in step S751 to the second polar decoder (S769). In other words, when the k-th transmission signal is an odd-numbered retransmission signal, the receiving node 750 may input the k-th bit set obtained in step S751 to the second polar decoder (S769). The k-th bit set input to the second polar encoder may be expressed as {s′₁, s′₂, . . . , s′_{2N}}. The second polar encoder may perform a decoding operation on the k-th bit set (S770). The second polar decoder may output second output bits v′ᵢ (i=1, 2, . . . , 2N) as a result of the decoding operation on the bits s′ᵢ included in the k-th bit set. The decoding operation according to step S770 may be performed based on the iterative decoding scheme or the MAP decoding scheme described with reference to FIG. 4B. Here, in the decoding operation according to step S770, a priori information term updated based on the first priori information bit set obtained as a result of interleaving the (k−1)-th bit set may be used.

When an error is not identified in the decoding operation according to step S770, the receiving node 750 may transmit an ACK signal to the transmitting node 700. When an error is not identified in the decoding operation in step S770, the receiving node 750 may obtain a result of restoring the interleaved bits vᵢ (i=1, 2, . . . , N) and/or the information bits uᵢ (i=1, 2, . . . , N) the the transmitting node 700 intended to transmit, based on bits excluding bits corresponding to the frozen bits among the second output bits v′ᵢ (i=1, 2, . . . , 2N). The receiving node 750 may output the obtained restoration result (S790).

On the other hand, when an error is identified in the decoding operation according to step S770, the receiving node 750 may transmit a NACK signal according to the HARQ scheme to the transmitting node 700. When an error is identified in the decoding operation in step S770, the receiving node 750 may input the second output bits v′ᵢ (i=1, 2, . . . , 2N) to the deinterleaver. The deinterleaver included in the receiving node 750 may be the same as or similar to the deinterleaver 675 described with reference to FIG. 6D or the deinterleaver 675 described with reference to 6E. The deinterleaver may have a structure in which N is changed to 2N from the deinterleaver 675 described with reference to FIG. 6E. The receiving node 750 may perform deinterleaving on the second output bits v′ᵢ (i=1, 2, . . . , 2N) through the deinterleaver (S775). The deinterleaver may output second priori information bits t′ᵢ (i=1, 2, . . . , 2N) as a result of the deinterleaving operation (S776). Here, the second priori information bits t′ᵢ and the second output bits v′ᵢ may have a relationship as shown in Equation 7.

t″ᵢ=v″_{2N+1-i} (i=1, 2, . . . , 2N) [Equation 7]

The second priori information bits may be input to the first polar decoder (S776). The second prior information bits may be used for a decoding operation in the first polar decoder.

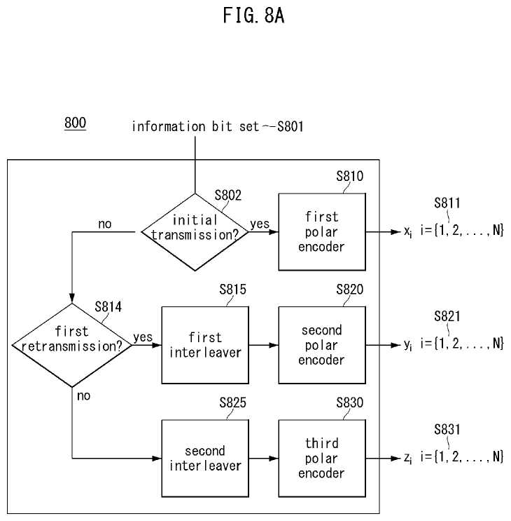

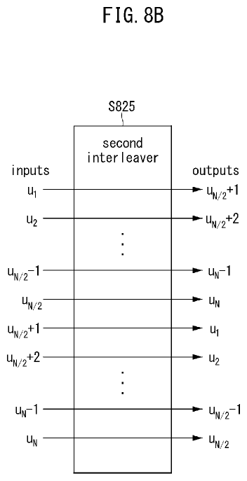

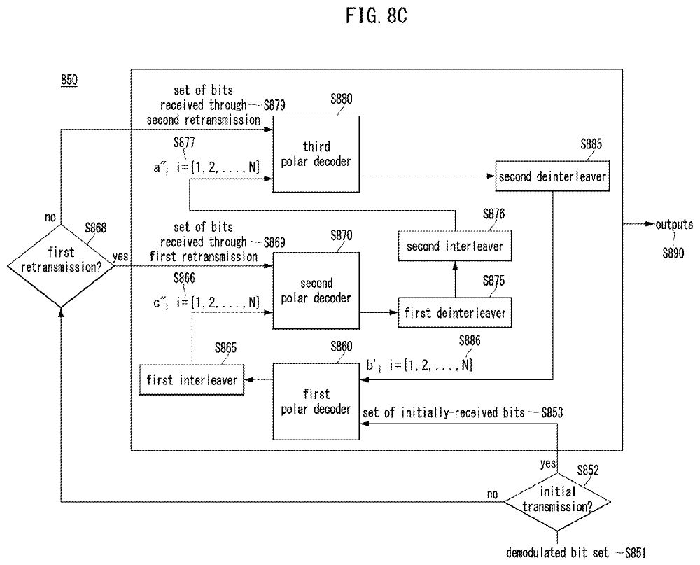

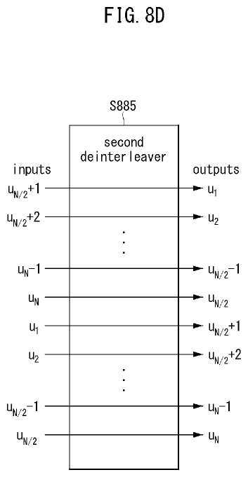

FIGS. 8A to 8D are conceptual diagrams for describing a second exemplary embodiment of a method for transmitting and receiving a signal by a transmitting node and a receiving node in a communication system.

Referring to FIGS. 8A to 8D, in a communication system, a transmitting node 800 and a receiving node 850 may transmit and receive signals based on a polar coding scheme. The transmitting node 800 may include a plurality of polar encoders to encode information bits to be transmitted to the receiving node 850. Here, a first polar encoder included in the transmitting node 800 may be the same as or similar to the first polar encoder described with reference to FIG. 7A. A second polar encoder included in the transmitting node 800 may be the same as or similar to the second polar encoder 620 described with reference to FIG. 7A. Bits interleaved by a first interleaver included in the transmitting node 800 may be input to the second polar encoder, and polar encoding may be performed thereon. The first interleaver included in the transmitting node 800 may be the same as or similar to the interleaver described with reference to FIG. 7A.

The receiving node 850 may receive a signal transmitted from the transmitting node 800. The receiving node 850 may include a first polar decoder and a second polar decoder to restore the information bits by decoding demodulated bits obtained by demodulating the received signal. The first polar decoder included in the receiving node 850 may be the same as or similar to the first polar decoder 660 described with reference to FIG. 6D. The second polar decoder included in the receiving node 850 may be the same as or similar to the second polar decoder 670 described with reference to FIG. 6D. In the second polar decoder, a decoding operation according to the MAP scheme may be performed, and the bits interleaved by the first interleaver may be used for the decoding operation according to the MAP scheme. The first interleaver may be the same as or similar to the interleaver included in the receiving node 750 described with reference to FIG. 7B. Bits output from the second polar decoder may be input to a first deinterleaver included in the receiving node 850, and deinterleaved through the first deinterleaver. The first deinterleaver may be the same as or similar to the deinterleaver included in the receiving node 750 described with reference to FIG. 7B.

Meanwhile, when the transmitting node 800 and the receiving node 850 perform retransmission twice due to a transmission/reception failure, they may include an additional structure for obtaining different coding gains through the respective transmission rounds. For example, the transmitting node 800 may include a second interleaver and a third polar encoder, and the receiving node 850 may further include a second interleaver, a second deinterleaver, and a third polar decoder. The third polar encoder may be a polar encoder having the same or similar structure as the first and second polar encoders. The third polar decoder may be a polar decoder having the same or similar structure as the first and second polar decoders. The second interleaver included in the transmitting node 800 may be the same as or similar to the second interleaver shown in FIG. 8B. The second interleaver included in the receiving node 850 may be the same as or similar to the second interleaver shown in FIG. 8B. The second deinterleaver included in the receiving node 850 may be the same as or similar to the second deinterleaver shown in FIG. 8D.

Hereinafter, in describing the second exemplary embodiment of the method for transmitting and receiving a signal by the transmitting node and the receiving node in the communication system with reference to FIGS. 8A to 8D, contents overlapping those described with reference to FIGS. 3 to 7B may be omitted.

Referring to FIG. 8A, the transmitting node 800 may include the first polar encoder and the second polar encoder. The transmitting node 800 may encode an information bit set {u₁, u₂, . . . u₈} corresponding to information or data to be transmitted to the receiving node 850 using the polar coding scheme.

The transmitting node 800 may identify an information bit set {u₁, u₂, . . . u_{N}} to be transmitted to the receiving node 850 (S801). The transmitting node 800 may identify which transmission round the information bit set {u₁, u₂, . . . u_{N}} to be initially transmitted or retransmitted to the receiving node 850 belongs to (S801). The transmitting node 800 may identify whether transmission of the information bit set to be transmitted to the receiving node 850 corresponds to initial transmission (S802).

When the information bit set is initially transmitted (S802), the transmitting node 800 may encode N information bits included in the information bit set through the first polar encoder (S810). The encoding operation according to step S810 may be the same as or similar to the encoding operation of the first polar encoder 610 described with reference to FIG. 6A. The first polar encoder may output 2N coded bits xᵢ (i=1, 2, . . . , 2N) as a result of encoding the information bits (S811). The transmitting node 800 may generate an initial transmission signal by modulating the 2N coded bits xᵢ output from the first polar encoder. The transmitting node 800 may transmit the initial transmission signal to the receiving node 850.

Meanwhile, when the information bits are retransmitted (S802), the transmitting node 800 may identify whether or not they are retransmitted as first retransmission (S814). When the information bit set is retransmitted as first retransmission, the transmitting node 800 may encode the N information bits included in the information bit set through the second polar encoder (S820). Specifically, when the information bits are transmitted as first retransmission (S814), the transmitting node 800 may input the N information bits included in the information bit set to the first interleaver. Here, the first interleaver may be the same as or similar to the interleaver included in the transmitting node 700 described with reference to FIG. 7A. The first interleaver may generate or obtain a first interleaved bit set through an interleaving operation (S815) on the input information bit set {u₁, u₂, . . . u_{N}}. The transmitting node 800 may input the first interleaved bit set to the second polar encoder. Here, the second polar encoder may be the same as or similar to the second polar encoder described with reference to FIG. 7A. The second polar encoder may perform encoding on the first interleaved bits (S820). The encoding operation according to step S820 may be the same as or similar to the encoding operation S720 of the first polar encoder described with reference to FIG. 7A. The second polar encoder may output 2N coded bits yᵢ (i=1, 2, . . . , 2N) as a result of encoding the first interleaved bits (S821). The transmitting node 800 may generate a first retransmission signal by modulating the 2N coded bits yᵢ output from the second polar encoder. The transmitting node 800 may transmit the first retransmission signal to the receiving node 850.

On the other hand, when the information bit set to be retransmitted is not retransmitted as first retransmission (e.g., when it is retransmitted as second retransmission) (S814), the transmitting node 800 may encode the N information bits included in the information bit set through the third polar encoder (S830). Specifically, when the information bits are retransmitted as second retransmission (S814), the N information bits included in the information bit may be input to the second interleaver. Here, the second interleaver may be the same as or similar to the second interleaver shown in FIG. 8B. The second interleaver may generate or obtain a second interleaved bit set through an interleaving operation (S825) on the input information bit set {u1, u2, . . . uN}. The transmitting node 800 may input the second interleaved bit set to the third polar encoder. The third polar encoder may perform encoding on second interleaved bits (S830). The third polar encoder may output 2N coded bits zi (i=1, 2, . . . , 2N) as a result of encoding the second interleaved bits (S831). The transmitting node 800 may generate a second retransmission signal by modulating the 2N coded bits zi output from the second polar encoder. The transmitting node 800 may transmit the second retransmission signal to the receiving node 850.

In FIG. 8A, an exemplary embodiment of a method for transmitting and receiving a signal has been described based on the exemplary embodiment in which the transmitting node 800 performs encoding operations based on the first polar encoder, the second polar encoder, and the third polar encoder that are different from each other. However, this is only an example for convenience of description, and exemplary embodiments of the present disclosure are not limited thereto. For example, in another exemplary embodiment of the signal transmission/reception method, the transmitting node 800 may perform the encoding operation according to steps S810, S820, and/or S830 through one polar encoder.

Referring to FIG. 8C, the receiving node 850 may receive a signal transmitted from the transmitting node 800. The receiving node 850 may demodulate the signal transmitted from the transmitting node 800 to obtain a demodulated bit set. The receiving node 850 may identify whether the transmission of the demodulated bit set corresponds to initial transmission (S852).

When the demodulated bit set is received through initial transmission (S852), the receiving node 850 may input a demodulated bit set obtained in step S851 (hereinafter, a first demodulated bit set) to the first polar decoder (S853). The first polar encoder may perform a decoding operation on the input bit set (S860). The first polar decoder may output first output bits as a result of the decoding operation on the bits included in the input bit set. The decoding operation according to step S860 may be performed based on the iterative decoding scheme or the MAP decoding scheme described with reference to FIG. 4B.

When an error is not identified in the decoding operation according to step S860, the receiving node 850 may transmit an ACK signal according to the HARQ scheme to the transmitting node 800. When an error is not identified in the decoding operation in step S860, the receiving node 850 may determine that N bits excluding bits corresponding to the frozen bits among the first output bits correspond to a result of restoring the information bits uᵢ (i=1, 2, . . . , N) that the transmitting node 800 intended to transmit. The receiving node 850 may output the bits corresponding to the restoration result of the information bits uᵢ (i=1, 2, . . . , N) (S890).

On the other hand, when an error is identified in the decoding operation according to step S860, the receiving node 850 may transmit a NACK signal according to the HARQ scheme to the transmitting node 800. When an error is identified in the decoding operation in step S860, the receiving node 850 may input the first output bits to a first interleaver. The first interleaver included in the receiving node 850 may be the same as or similar to the interleaver included in the receiving node 750 described with reference to FIG. 7B. The receiving node 850 may perform interleaving on the first output bits through the first interleaver (S865). The interleaver may output first priori information bits c″ᵢ (i=1, 2, . . . , 2N) as a result of the interleaving operation (S866).

The receiving node 850 may input a first priori information bit set {c″₁, c″₂, . . . , c″_{2N}} including first priori information bits c″ᵢ to the second polar decoder. The second polar decoder may calculate the priori information term described with reference to FIG. 4B based on the first priori information bit set. In other words, the second polar decoder may update the priori information term based on the first priori information bit set generated by interleaving the first output bit set output from the first polar decoder through the first interleaver. The second polar decoder may perform decoding on a second demodulated bit set based on the updated priori information term and the second demodulated bit set (hereinafter referred to also as second demodulated bits) obtained by receiving and demodulating a first retransmission signal.

On the other hand, when the demodulated bit set is received as retransmission (S852), it may be identified whether the demodulated bit set is a result of demodulating the first retransmission signal (S868). When the demodulated bit set is a result of demodulating the first retransmission signal (S868), the receiving node 850 may input the demodulated bit set (hereinafter referred to as ‘second demodulated bit set’) obtained in step S851 to the second polar decoder (S869). The second polar encoder may perform a decoding operation on the second demodulated bit set (S870). The second polar decoder may output second output bits as a result of the decoding operation on the second demodulated bits. The decoding operation according to step S870 may be performed based on the iterative decoding scheme or the MAP decoding scheme described with reference to FIG. 4B. Here, in the decoding operation according to step S870, a priori information term updated based on the decoded and interleaved first priori information bit set for the first demodulated bit set may be used.

When an error is not identified in the decoding operation according to step S870, the receiving node 850 may transmit an ACK signal to the transmitting node 800. When an error is not identified in the decoding operation in step S870, the receiving node 850 may obtain a result of restoring that first interleaved bits or transmission bits uᵢ (i=1, 2, . . . , N) that the transmitting node 800 intended to transmit based on bits excluding bits corresponding to the frozen bits among the second output bits. The receiving node 850 may output the obtained restoration result (S890).

On the other hand, when an error is identified in the decoding operation according to step S870, the receiving node 850 may transmit a NACK signal according to the HARQ scheme to the transmitting node 800. When an error is identified in the decoding operation in step S870, the receiving node 850 may input the second output bits to the first deinterleaver. The first deinterleaver included in the receiving node 850 may be the same as or similar to the deinterleaver described with reference to FIG. 7B. The receiving node 850 may perform deinterleaving on the second output bits through the first deinterleaver (S875). The bits output as a result of the first deinterleaving operation in the first deinterleaver may be input to a second interleaver. The second interleaver may be the same as or similar to the second interleaver shown in FIG. 8B. The second interleaver may perform an interleaving operation to output second priori information bits a′ᵢ (i=1, 2, . . . , 2N) (S876).

On the other hand, when the demodulated bit set is not a result of demodulating a first retransmission signal (e.g., when it is a result of demodulating a second retransmission signal) (S868), the receiving node 850 may input the demodulated bit set (hereinafter, referred to also as ‘third demodulated bit set’) obtained in step S851 to the third polar decoder (S879). The third polar encoder may perform a decoding operation on the third demodulated bit set (S880). The third polar decoder may output third output bits as a result of the decoding operation on the third demodulated bits. The decoding operation according to step S880 may be performed based on the iterative decoding scheme or the MAP decoding scheme described with reference to FIG. 4B. Here, in the decoding operation according to step S880 (i.e., the decoding operation (S870) in the second polar encoder for the second demodulated bit set input to the second polar encoder (S869)), the priori information term updated based on the second priori bit set obtained through the deinterleaving in the first deinterleaver (S875) and the interleaving in the second interleaver (S876) may be used.

When an error is not identified in the decoding operation according to step S880, the receiving node 850 may transmit an ACK signal to the transmitting node 800. When an error is not identified in the decoding operation in step S880, the receiving node 850 may obtain a result of restoring second interleaved bits and/or transmission bits uᵢ (i=1, 2, . . . , N) that the transmitting node 800 intended to transmit based on bits excluding bits corresponding to the frozen bits among the third output bits. The receiving node 850 may output the obtained restoration result (S890).

On the other hand, when an error is identified in the decoding operation according to step S880, the receiving node 850 may transmit a NACK signal according to the HARQ scheme to the transmitting node 800. When an error is identified in the decoding operation in step S880, the receiving node 850 may input the third output bits to the second deinterleaver. The second deinterleaver included in the receiving node 850 may be the same as or similar to the second deinterleaver described with reference to FIG. 8D. The receiving node 850 may perform deinterleaving on the third output bits through the second deinterleaver (S885). Bits output as a result of the second deinterleaving operation in the second deinterleaver may be input to the first polar encoder as third prior information bits b′ᵢ (i=1, 2, . . . , 2N) (S886).

In FIGS. 8A and 8C, the second exemplary embodiment of the method for transmitting and receiving a signal by the transmitting node and the receiving node has been described assuming an exemplary embodiment in which retransmission is performed twice according to a transmission/reception failure. However, this is only an example for convenience of description, and exemplary embodiments of the present disclosure are not limited thereto. For example, if retransmission is performed three or more times, the transmitting node 800 may encode an information bit set to be retransmitted as the 3m-th retransmission (m is a natural number greater than or equal to 1) through the first polar encoder (S810), and may transmit bits output as a result of encoding in the first polar encoded by modulating the bits. The transmitting node 800 may encode an information bit set to be retransmitted as the (3m+1)-th retransmission by using the second polar encoder (S820) after interleaving in the first interleaver (S815), and transmit bits output as a result of the encoding in the second polar encoder (S821) by modulating the bits. The transmitting node 800 may encode an information bit set to be retransmitted as the (3m+2)-th retransmission by using the third polar encoder (S830) after interleaving in the second interleaver (S825)), and transmit bits output as a result of the encoding in the second polar encoder (S831) by modulating the bits

Meanwhile, if retransmission is performed three or more times, the receiving node 850 may perform decoding a bit set (hereinafter, referred to as ‘( 3 m−1)-th modulate bit set) demodulated and received through the 3m-th retransmission by inputting the bit set to the first polar decoder (S860). The decoding operation according to step S860 for the (3m+1)-th demodulated bit set may be performed based on the iterative decoding scheme or the MAP decoding scheme described with reference to FIG. 4B. Here, in the decoding operation (S860) of the (3m+1)-th demodulated bit set in the first polar encoder, a priori information term updated based on a third priori information bit set obtained through the decoding (S880) in the third polar decoder and deinterleaving (S885) in the second deinterleaver may be used. The receiving node 850 may decode a bit set obtained by receiving and demodulating the (3m+1)-th retransmission (hereinafter, referred to also as ‘3m+2’-th demodulated bit set) (S870) by inputting it to the second polar decoder (S869). The receiving node 850 may decode a bit set obtained by receiving and demodulating the (3m+2)-th retransmission (hereinafter, referred to also as ‘3m+3’-th demodulated bit set) (S880) by inputting it to the second polar decoder (S879).

According to exemplary embodiments of the HARQ method and apparatus in the communication system using polar codes, a transmitting node that transmits a signal based on the polar coding scheme may perform encoding on transmission bits by using different polar encoders or the same polar encoder during initial transmission and during HARQ retransmission. In HARQ retransmission, encoding is performed using an interleaver. The interleaver performs mapping by applying different relationships between input bits to the initial transmission and the retransmission, so that a probability (i.e., belief) of 1 and a probability of 0 can be propagated to each decoder (i.e., belief propagation) for the initial transmission and the retransmission.

Since the conventional polar encoder does not include an interleaver and the conventional polar decoder does not include a deinterleaver and an interleaver, a coding gain is obtained only with polarization characteristics. According to the present disclosure, an interleaver may be included in a polar encoder of a transmitting node, and a deinterleaver and an interleaver may be included in a polar decoder of a receiving node to perform transmission and reception for retransmission, thereby deriving characteristics of belief propagation that can be provided by the interleaver and deinterleaver, and improving a channel coding gain through the polarization characteristics and belief propagation characteristics of the polar codes. The receiving node receiving a signal based on the polar coding scheme may perform decoding of transmission bits by using different polar decoders or the same polar decoder for a case of receiving an initially transmitted signal and a case of receiving a retransmitted signal. In the case of decoding retransmitted data, decoding is performed by inputting the data to each decoder using the deinterleaver and the interleaver.

Alternatively, the transmitting node and the receiving node transmitting a signal based on the polar coding scheme may encode and decode a signal transmitted/received as odd-numbered transmission and a signal transmitted/received as even-numbered transmission by using different polar encoders and polar decoders. In this case, the even-numbered transmission signal is input to the encoder after interleaving, and the received signal is decoded by performing deinterleaving and interleaving on an output signal of each decoder.

Alternatively, the transmitting node and the receiving node transmitting a signal based on the polar coding scheme may encode and decode a signal transmitted/received as odd-numbered transmission and a signal transmitted/received as even-numbered transmission by using the same polar encoder and the same polar decoder. In this case, the even-numbered transmission signal is input to the encoder after interleaving, and the received signal is decoded by performing deinterleaving and interleaving on an output signal of each decoder. Through this, a coding gain can be further maximized and performance of transmission and reception operations can be improved due to the channel polarization characteristics and belief propagation characteristics of the polar coders according to the interleaving and deinterleaving.

However, the effects that can be achieved by the method and apparatus for transmitting and receiving signals in a communication system according to the exemplary embodiments of the present disclosure are not limited to those mentioned above, and other effects not mentioned will be clearly understood by those skilled in the art to which the present disclosure belongs from the configurations described in the specification of the present disclosure.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. An operation method of a transmitting node in a communication system, the operation method comprising:
generating 2N initial transmission bits by encoding N information bits to be transmitted to a receiving node of the communication system in a polar coding scheme, wherein N is a natural number equal to or greater than 1;
transmitting, to the receiving node, an initial transmission signal generated by modulating the 2N initial transmission bits;
receiving, from the receiving node, a signal indicating that the initial transmission signal is not normally received;
interleaving the N information bits through an interleaver to generate N interleaved bits;
generating 2N first retransmission bits by encoding the N interleaved bits in the polar coding scheme; and
transmitting, to the receiving node, a first retransmission signal generated by modulating the 2N first retransmission bits.

2. The operation method according to claim 1, wherein the generating of the 2N initial transmission bits comprises:
inputting the N information bits and N frozen bits to a first polar encoder having 2N bit channels; and
obtaining the 2N initial transmission bits output from the first polar encoder.

3. The operation method according to claim 1, wherein the generating of the 2N first retransmission bits comprises:
inputting the N interleaved bits and N frozen bits to a second polar encoder having 2N bit channels; and
obtaining the 2N first retransmission bits output from the second polar encoder.

4. The operation method according to claim 1, further comprising:
receiving, from the receiving node, a signal indicating that a k-th retransmission signal transmitted to the receiving node is not normally received, wherein k is a natural number equal to or greater than 1;
generating 2N (k+1)-th retransmission bits; and
transmitting, to the receiving node, a (k+1)-th retransmission signal generated by modulating the 2N (k+1)-th retransmission bits,
wherein the 2N (k+1)-th retransmission bits correspond to a result of encoding the N interleaved bits in the polar coding scheme when k is an odd number, and correspond to a result of encoding the N information bits in the polar coding scheme when k is an even number.

5. The operation method according to claim 1, wherein the polar coding scheme means an encoding scheme by a polar encoder having 2N bit channels, and N bit channels to which N frozen bits are inputted among the 2N bit channels are determined based on mutual information (MI) values of the respective 2N bit channels.

6. An operation method of a receiving node in a communication system, the operation method comprising:
receiving a first transmission signal initially transmitted from a transmitting node of the communication system;
performing a decoding operation on 2N first received bits obtained by demodulating the first transmission signal in a polar coding scheme, wherein N is a natural number equal to or greater than 1;
transmitting, to the transmitting node, a signal indicating that the initially transmitted first transmission signal is not normally received, when an error is identified in the decoding operation on the 2N first received bits;
generating 2N first interleaved bits by interleaving 2N first output bits output as a result of the decoding operation on the 2N first received bits;
receiving a second transmission signal transmitted from the transmitting node based on the signal indicating that the initially transmitted first transmission signal is not normally received;
demodulating the second transmission signal to obtain 2N second received bits;
performing a decoding operation on the 2N second received bits based on the 2N first interleaved bits in the polar coding scheme; and
restoring N information bits based on a result of the decoding operation on the 2N second received bits.

7. The operation method according to claim 6, wherein the performing of the decoding operation on the 2N first received bits comprises:
inputting the 2N first received bits to a first polar decoder having 2N bit channels;
performing, by the first polar decoder, the decoding operation on the 2N first received bits;
obtaining the 2N first output bits output from the first polar decoder, when no error is identified in the decoding operation on the 2N first received bits; and
determining remaining N first output bits excluding N first output bits corresponding to frozen bits among the 2N first output bits as a result of restoring the N information bits.

8. The operation method according to claim 6, wherein the performing of the decoding operation on the 2N second received bits comprises:
inputting the 2N first interleaved bits to a second polar decoder having 2N bit channels;
updating a second priori information term used in a decoding operation in the second polar decoder based on the 2N first interleaved bits;
inputting the 2N second received bits to the second polar decoder;
performing, by the second polar decoder, the decoding operation on the 2N second received bits based on the updated second priori information term and the 2N second received bits;
obtaining 2N second output bits output from the second polar decoder as a result of the decoding operation on the 2N second received bits, when no error is identified in the decoding operation on the 2N second received bits; and
determining N remaining second output bits excluding N second output bits corresponding to frozen bits among the 2N second output bits as a result of restoring the N information bits.

9. The operation method according to claim 6, wherein the performing of the decoding operation on the 2N second received bits comprises:
inputting the 2N first interleaved bits to a second polar decoder having 2N bit channels;
updating a second prior information term used in a decoding operation in the second polar decoder based on the 2N first interleaved bits;
inputting the 2N second received bits to the second polar decoder;
performing, by the second polar decoder, the decoding operation on the 2N second received bits based on the updated second prior information term and the 2N second received bits;
transmitting, to the transmitting node, a signal indicating that the second transmission signal is not normally received, when an error is identified in the decoding operation on the 2N second received bits;
generating 2N first deinterleaved bits by deinterleaving 2N second output bits output from the second polar decoder as a result of the decoding operation on the 2N second received bits; and
inputting the 2N first deinterleaved bits to a first polar decoder having 2N bit channels.

10. The operation method according to claim 9, further comprising:
demodulating a (k+1)-th transmission signal transmitted from the transmitting node to obtain 2N (k+1)-th received bits, based on a signal indicating that a k-th transmission signal is not normally received, wherein k is a natural number equal to or greater than 1;
updating a j-th priori information term used in a decoding operation in a j-th polar decoder, based on 2N k-th interleaved bits obtained by interleaving 2N k-th output bits output as a result of a decoding operation on 2N k-th received bits obtained by demodulating the k-th transmission signal;
inputting the 2 N-th (k+1)-th received bits to the j-th polar decoder; and
performing, by the j-th polar decoder, a decoding operation on the 2N (k+1)-th received bits, based on the updated j-th priori information term and the 2N (k+1)-th received bits,
wherein the j-th polar decoder corresponds to the second polar decoder when k is an odd number, and the j-th polar decoder corresponds to the first polar decoder when k is an even number.

11. A transmitting node transmitting signals to a receiving node in a communication system, the transmitting node comprising:
a processor;
a memory electronically communicating with the processor; and
instructions stored in the memory,
wherein when executed by the processor, the instructions cause the transmitting node to perform:
generating 2N initial transmission bits by encoding N information bits to be transmitted to a receiving node of the communication system in a polar coding scheme, wherein N is a natural number equal to or greater than 1;
transmitting, to the receiving node, an initial transmission signal generated by modulating the 2N initial transmission bits;
receiving, from the receiving node, a signal indicating that the initial transmission signal is not normally received;
interleaving the N information bits through an interleaver to generate N interleaved bits;
generating 2N first retransmission bits by encoding the N interleaved bits in the polar coding scheme; and
transmitting, to the receiving node, a first retransmission signal generated by modulating the 2N first retransmission bits.

12. The transmitting node according to claim 11, wherein in the generating of the 2N initial transmission bits, the instructions further cause the transmitting node to perform:
inputting the N information bits and N frozen bits to a first polar encoder having 2N bit channels; and
obtaining the 2N initial transmission bits output from the first polar encoder.

13. The transmitting node according to claim 11, wherein in the generating of the 2N first retransmission bits, the instructions further cause the transmitting node to perform:
inputting the N interleaved bits and N frozen bits to a second polar encoder having 2N bit channels; and
obtaining the 2N first retransmission bits output from the second polar encoder.

14. The transmitting node according to claim 11, wherein the instructions further cause the transmitting node to perform:
receiving, from the receiving node, a signal indicating that a k-th retransmission signal transmitted to the receiving node is not normally received, wherein k is a natural number equal to or greater than 1;
generating 2N (k+1)-th retransmission bits; and
transmitting, to the receiving node, a (k+1)-th retransmission signal generated by modulating the 2N (k+1)-th retransmission bits,
wherein the 2N (k+1)-th retransmission bits correspond to a result of encoding the N interleaved bits in the polar coding scheme when k is an odd number, and correspond to a result of encoding the N information bits in the polar coding scheme when k is an even number.
